(19) United States
(12) Patent Application Publication
(10) Pub. No.: US 2010/0243020 A1
(43) Pub. Date: Sep. 30, 2010

(54) HYBRID STRUCTURES FOR SOLAR ENERGY CAPTURE

(75) Inventors: M. Grant Norton, Pullman, WA (US); David N. McIlroy, Moscow, ID (US)

Correspondence Address: PERKINS COIE LLP;PATENT-SEA, P.O. BOX 1247, SEATTLE, WA, 98111-1247, US

(73) Assignees: WASHINGTON STATE UNIVERSITY RESEARCH FOUNDATION, Pullman, WA (US); UNIVERSITY OF IDAHO, Moscow, ID (US)

(21) Appl. No.: 12/159,543

(22) PCT Filed: Jun. 20, 2008
(86) PCT No.: PCT/US08/67768

§ 371 Date: Jun. 27, 2008

Related U.S. Application Data
(60) Provisional application No. 60/936,787, filed on Jun. 22, 2007.

(51) Int. Cl. H01L 31/042; H01L 31/18; H01L 31/00

(52) U.S. Cl. 136/244; 438/63; 136/261; 977/773; 257/E31.032; 257/E31.124

(57) ABSTRACT

A solar energy capture device (solar cell) comprising a disordered mat of semiconductor nanostructures decorated with metal nanoparticles of varying diameters is described. The solar cell may be configured as a semiconductor-type solar cell or as a Gratzel-type solar cell.

### CROSS REFERENCE TO RELATED APPLICATIONS

This application claims the benefit of priority to U.S. Provisional Patent Application Ser. No. 60/936,787, entitled “Hybrid Structures for Solar Energy Capture,” filed Jun. 22, 2007, which is hereby incorporated by reference herein in its entirety.

### FIELD

The present application relates generally to solar energy capture devices for use in photovoltaic systems. More specifically, this application relates to hybrid solar energy capture devices comprising nanostructures and nanoparticles.

### BACKGROUND

More energy strikes the Earth in one hour (4.3×10²⁰ J) than all the energy consumed on the planet in a year (4.1×10²⁰ J, equivalent to a continuous power consumption of 13 TW). Yet, solar energy provides less than 0.1% of the world's electricity. The huge gap between our present use of solar energy and its enormous undeveloped potential defines a grand challenge in energy research.

Currently silicon (Si) is the dominant material employed within the fabrication of solar cells that are utilized to convert sunlight to useable energy. Single and multi junction p-n solar cells are currently used for this purpose, yet the energy conversion efficiency attainable from such systems relative to the energy required for their manufacture has made the widespread implementation of such systems economically impractical. However, solar cells based on Si can be expensive to manufacture, even those utilizing amorphous Si.

Alternative solar cells have been developed based on organic compounds and/or a mixture of organic and inorganic compounds. Solar cells of the latter type are often referred to as hybrid solar cells. Organic and hybrid solar cells have proved to be cheaper to manufacture, but can have low efficiencies, even when compared to amorphous Si cells. Due to inherent advantages such as low-weight and low-cost fabrication of large areas, earth-friendly materials, and/or preparation on flexible substrates, efficient organic devices might prove to be technically and commercially useful “plastic solar cells.” Recent progress in solar cells based on dye-sensitized nanocrystalline titanium dioxide (porous TiO₂) semiconductors and liquid redox electrolytes demonstrate the possibility of high energy conversion efficiencies in organic materials (approximately 11%). Examples of dye-sensitized nanocrystalline titanium dioxide are provided in B. O'Regan and M. Grätzel, Nature 353, 737 (1991), which is hereby incorporated by reference herein in its entirety.

Thus, a need exists for improved solar cells, e.g., solar cells with increased efficiency and/or solar cells that can absorb a greater fraction of the solar energy spectrum to generate increased current.

### SUMMARY

Herein, novel approaches to light capture and conversion are provided. Generally, the extraordinary properties of metal or metal alloy nanoparticles (MNPs) are exploited herein as a primary means for light capture, while differing mechanisms for the generation of photocurrent are provided. Common to the photocurrent generation mechanisms is the use of nanostructure (nanowire, nanospring, nanotube and/or nanorod) scaffolds as support structures for light harvesting metal nanoparticles. In certain implementations, a distribution of MNPs is disposed on the exterior of a nanostructure so that the MNPs are exposed to an external environment, e.g., to provide kinetic access to the external environment, while in some implementations MNPs may be incorporated into the bulk of the nanostructure, as described in further detail below.

In each approach, a contiguous mat of semiconductor nanostructures grown on a conductive or semiconducting substrate serve as the fundamental scaffolding for the photon harvesting MNPs. One feature of the approach described herein is the inherent disorder and thickness or depth of the mats. For example, a mat may have a depth (thickness) extending outwardly from a surface of a conductive or semiconducting substrate, e.g., about 10 microns to about 500 microns, about 10 microns to about 400 microns, about 10 microns to about 300 microns (e.g., about 30 microns to about 300 microns), about 10 microns to about 200 microns of the contiguous mat of nanostructures, or about 10 microns to about 100 microns. A mat depth may be selected to tune absorption of solar radiation by the mat, e.g., a thicker mat may have higher absorption, and hence may contribute to increased photocurrent generation. In certain variations, the disordered mats may enable a greater degree of photon capture due to an enhanced internal reflection within the disordered mat and/or disordered mats may enable enhanced diffusive properties for more facile nanostructure surface modification and/or surface particle regeneration.

As used herein, the terms “nanostructure” and “nanoparticle” are meant to include any structure or particle, respectively, having a cross-sectional dimension of about 1000 nm or smaller, e.g., a dimension of about 1 nm to about 1000 nm, or about 100 nm or smaller. Nanosprings, nanowires, nanotubes, and nanorods are all examples of nanostructures. An “average” value is meant to encompass a median, mean, mode, or any typical value for a population. “Aspect ratio” as used herein refers to a ratio of one cross-sectional dimension to another cross-sectional dimension of a particle or structure, e.g., a ratio of a relatively long cross-sectional dimension to a relatively short cross-sectional dimension. As used herein, a material composed “primarily” of an ingredient comprises at least about 50% (by weight or by volume) of that ingredient. Numerical ranges as used herein are meant to encompass any end points for the ranges, as well as numerical values between the end points. Singular referants such as “a” “an” and “the” are meant to encompass plural referants as well, unless the context clearly indicates otherwise.

Solar energy capture devices (solar cells) are provided herein. The devices comprise a first conductive or semiconducting electrode substrate and a first mat disposed on and in electrical contact with the first electrode substrate. The first mat comprises a plurality of semiconducting nanostructures that may, for example, be oriented in a substantially disordered manner. A plurality of metal or metal alloy nanoparticles is disposed on the nanostructures. The nanoparticles have a distribution of sizes and/or shapes. The devices are configured so that the first mat receives and absorbs incident solar radiation to result in charge carrier generation in the nanostructures.

In general, the nanoparticles may comprise any suitable metal and/or metal alloy. In certain variations, the nanoparticles may comprise a metal or metal alloy comprising gold, silver, copper, platinum, palladium, nickel, or a combination thereof.

The metal or metal alloy nanoparticles may be used to tune the absorption properties of a mat, and hence the absorption properties of a solar energy capture device comprising that mat. For example, an absorption spectrum of a mat may be tuned by adjusting a width of a size distribution and/or a shape distribution of the plurality of nanoparticles. An absorption spectrum of a mat may be tuned by adjusting an average size of the plurality of nanoparticles. In some cases, the nanoparticles may be non-spherical, and an absorption spectrum of a mat may be tuned by adjusting a width of a distribution of aspect ratios for the plurality of nanoparticles and/or an average aspect ratio of the plurality of nanoparticles. The plurality of nanoparticles may exhibit a variety of types of distributions in size and or shape (e.g., aspect ratio). For example, such a distribution may be monomodal (e.g., a symmetrical distribution such as a Gaussian distribution or skewed monomodal distribution) or multi-modal (e.g., bimodal).

In some variations, the nanoparticles may be used to extend the absorption range of a solar energy capture device, e.g., to wavelengths not typically absorbed by semiconductors. For example, the nanoparticles may be used to extend the absorption range of a solar energy capture device from the ultraviolet to include visible, near infrared or infrared wavelengths (e.g., so that the absorption of the device ranges from the ultraviolet to wavelengths of about 600 nm or greater, e.g., to about 650 nm, to about 700 nm, to about 750 nm, to about 800 nm, to about 850 nm, to about 900 nm, to about 950 nm, to about 1000 nm, to about 1100 nm, to about 1200 nm, to about 1300 nm, to about 1400 nm, to about 1500 nm, to about 1600 nm, to about 1700 nm, to about 1800 nm, to about 1900 nm, or to about 2000 nm).

The nanostructures used in the solar energy capture devices may have any suitable shape and/or configuration. For example, at least some of the nanostructures may comprise nanosprings, nanowires, nanorods, nanotubes, or a combination thereof. The nanostructures may also have a distribution of sizes and/or shapes. For example, the nanostructures may have a distribution of cross-sectional dimensions, lengths, and/or shapes.

The nanostructures may comprise any suitable semiconductor material. For example, the nanostructures may comprise ZnO, SnO₂, In₂O₃, Al₂O₃, TiO₂, SiC, GaN, or a combination thereof. At least some of the nanostructures in a device may be primarily composed of a semiconductor (e.g., some nanostructures may be primarily composed of GaN).

In some variations, at least some of the semiconducting nanostructures in a device may comprise a core disposed at least partially within a shell. In those variations, metal or metal alloy nanoparticles may be disposed on the core and at least partially covered by the shell. Alternatively or in addition, metal or metal alloy nanoparticles may be disposed on the shell. The core may be insulating and the shell may be semiconducting, or the core may be semiconducting and the shell may be insulating. In certain variations, each of the core and the shell may be semiconducting. For example, one of the core and the shell may comprise a p-type semiconductor and the other of the core and the shell may comprise an n-type semiconductor, e.g., to provide a p-n junction between the core and the shell. An insulating core or shell may comprise silica, and a semiconducting core or shell may comprise GaN. When a shell is semiconducting, a shell may in some variations comprise semiconducting nanoparticles. For example, a shell may comprise nanoparticles comprising ZnO, TiO₂, SnO₂, In₂O₃, Al₂O₃, or a combination thereof.

Thus, in some variations of the devices, at least a portion of the nanostructures may comprise GaN, and at least a portion of the nanoparticles may comprise gold. In certain other variations, at least a portion of the nanostructures may comprise a silica core and a shell comprising ZnO nanoparticles, and gold nanoparticles may be disposed on the shell and/or on the silica core.

Certain devices may be configured to receive incident radiation at a substantially normal angle of incidence relative to the first electrode substrate to which the mat is attached. In other variations, the devices may be configured to receive incident solar radiation at a non-normal angle of incidence relative to the first electrode substrate, e.g., to increase a path length for the radiation through the mat.

The devices may be configured for a variety of mechanisms for generating a photocurrent. For example, in some variations, the first mat of semiconducting nanostructures may be in electrical connection with first and second conductive or semiconducting electrode substrates. Upon absorption of a photon by a MNP, a charge carrier may be created in the semiconducting nanostructures in the mat to generate a current flow between the first and second electrode substrates. In other variations, a device may be configured as a Grätzel type solar cell. That is, an electrolyte may be disposed between first and second conducting or semiconducting electrode substrates of the device. The electrolyte may be in contact with the nanostructures so that charge transfer occurs between the electrolyte and the semiconducting nanostructures, leading to current flow between the first and second electrode substrates. Given the potential for operation in both types of modes (i.e., with or without an electrolyte disposed between the electrodes) a new type of “dual functioning” solar cell is described herein.

In certain variations, the devices may comprise more than one mat of semiconducting nanostructures. That is, in addition to a first mat of semiconducting nanostructures disposed on the first electrode substrate, a device may comprise a second mat of semiconducting nanostructures disposed on and in electrical contact with a second conductive or semiconducting electrode substrate. Here again, the semiconducting nanostructures may be substantially disordered in the mat. Nanostructures disposed on the first electrode substrate and the nanostructures disposed on the second electrode substrate may have the same, similar, or different compositions. Metal or metal alloy nanoparticles may, but need not be, disposed on the nanostructures in the second mat. Devices comprising a second mat of nanostructures may be configured such that the first and second mats are in electrical contact with each other. Absorption of a photon by a MNP on a semiconducting nanostructure of the first or second mat can generate a charge carrier in that nanostructure which can travel between the first and second to generate a current in the device. In other variations, a device comprising a second mat of nanostructures may be configured as a Grätzel-type solar cell, wherein semiconducting nanostructures of at least one of the first and second mats are placed in contact with an electrolyte disposed between the first and second electrode substrates, and charge transfer occurs between the semiconducting nanostructures and the electrolyte to generate a photocurrent upon illumination of the device with solar radiation.

The solar energy capture devices may be incorporated into any suitable circuit. For example, the devices may be electrically connected to a load or a charge storage device in a circuit. Thus current generated in the devices may be used to drive a load, or used to charge the charge storage device.

The solar energy capture devices may be incorporated as part of a larger system for collecting solar energy. For example, one or more of the solar energy capture devices disclosed herein may comprise part of a group of multiple solar cells. The group of multiple solar cells may be interconnected, e.g., series connected. In some variations of the systems, each of the multiple solar cells may be configured to preferentially absorb different parts of the solar spectrum.

Methods for generating photocurrents are described herein. The methods comprise providing a solar energy capture device, the device comprising a mat of semiconducting nanostructures (e.g., substantially disordered nanostructures) disposed on and in electrical contact with a conductive or semiconducting first electrode substrate. A plurality of metal or metal alloy nanoparticles is disposed on the nanostructures. The methods comprise irradiating the solar energy capture device with solar radiation so that the MNPs absorb incident solar radiation to generate charge carriers in the nanostructures to generate a current.

In the methods, a distribution of the size and/or shape of the nanoparticles can be used to tune the absorption characteristics of the solar energy capture devices, as described above. For example, a width of a nanoparticle size distribution and/or a peak of the size distribution may be adjusted to expand the absorption spectrum of the solar energy capture device, e.g., to increase absorption at visible, near infrared or infrared wavelengths. In some cases, the methods may comprise adjusting a distribution of aspect ratios of nanoparticles to adjust the absorption spectrum of the solar energy capture devices. In the methods, the nanoparticles may comprise gold, silver, copper, platinum, nickel, alloys thereof and/or combinations thereof.

The semiconducting nanostructures (e.g., nanowires, nanosprings, nanotubes, nanorods or a combination thereof) used in the methods may have any configuration or composition as described herein. The nanostructures may comprise any suitable semiconducting material, e.g., ZnO, SnO₂, In₂O₃, Al₂O₃, TiO₂, SiC, GaN, or a combination thereof. Further, at least some of the nanostructures may be primarily composed of a semiconductor (e.g., some nanostructures may be primarily composed of GaN).

Some methods may employ semiconducting nanostructures that comprise a core disposed at least partially within a shell. In those variations, metal or metal alloy nanoparticles can be disposed on the core and be at least partially covered by the shell and/or the metal or metal alloy nanoparticles can be disposed on the shell. The core may be insulating and the shell may be semiconducting, or the core may be semiconducting and the shell may be insulating. In certain variations, each of the core and the shell can be semiconducting. For example, one of the core and the shell can comprise a p-type semiconductor and the other of the core and the shell can comprise an n-type semiconductor. Thus, an insulating core or shell can comprise silica, and a semiconducting core or shell can comprise GaN. When a shell is semiconducting, a shell may in some variations comprise semiconducting nanoparticles. For example, a shell may comprise nanoparticles comprising ZnO, TiO₂, SnO₂, In₂O₃, Al₂O₃, or a combination thereof.

Thus, some methods for generating current may comprise using a mat wherein at least some of the nanostructures comprise GaN, and at least a portion of the nanoparticles comprise gold. Other methods for generating current may comprise using a mat wherein at least a portion of the nanostructures comprise a silica core and a shell comprising ZnO nanoparticles, with gold nanoparticles disposed on the shell and/or on the silica core.

In the methods, any variation of the solar energy capture devices as described herein may be used. For example, the methods may be used with solar energy capture devices that comprise two electrodes with the mat in electrical contact with the two electrodes, so that a photocurrent can be generated between the two electrodes. In other variations of the methods, the solar energy capture device may be configured as a Grätzel-type solar cell, wherein an electrolyte is disposed between two electrodes, and charge is transferred between the nanostructures and the electrolyte to generate a current between the two electrodes.

The semiconductor nanostructures described herein might be integrated within or as part of a conventional semiconductor photovoltaic (PV) device such that the nanostructures become an integral part of the device. These devices comprise a semiconductor photovoltaic solar panel comprising a first electrode and a mat electrically connected to the first electrode and a second electrode. Each of the solar panel and the mat are configured to receive and absorb incident solar radiation. The mat comprises a plurality of semiconducting nanostructures (e.g., substantially disordered nanostructures) and a plurality of metal or metal alloy nanoparticles disposed on the nanostructures.

The devices are generally configured so that the solar panel and the mat each absorb a portion of the incident solar radiation to generate current. For example, the mat may be configured to extend the absorption of solar radiation by the device to the red relative to the solar panel, e.g., to wavelengths in the visible, near infrared, or infrared regions of the solar spectrum. Thus, devices may be configured to exhibit enhanced absorption at a wavelength in a range from about 500 nm to about 2000 nm compared to the solar panel.

An example of a semiconductor photovoltaic panel that can be used in these devices would be one that uses amorphous silicon, e.g., as a thin film. Another example of a semiconductor photovoltaic panel that can be used in these devices would be one that uses polycrystalline silicon, e.g., microcrystalline silicon. In a further example, a semiconductor photovoltaic panel may use single crystalline silicon.

These devices may have a variety of configurations. For example, in some variations, the solar panel may comprise a silicon layer (e.g., an amorphous silicon layer) disposed on the first electrode and the mat may be electrically connected to the first electrode via the silicon layer. In certain instances, an antireflective coating (e.g., an antireflective coating comprising ZnO) may be disposed between the silicon layer and the mat, so that the mat is electrically connected to the first electrode via the silicon layer and the antireflective coating.

Devices may be configured so that solar radiation is incident on the solar panel, and light transmitted through the solar panel is incident on the mat. In other variations, devices may be configured so that solar radiation is incident on the mat, and light transmitted through the mat is incident on the solar panel.

In certain cases, devices may be configured so that incident solar radiation passes through an electrode to be incident on an absorbing layer. In those cases, the electrode may comprise a metal and may be patterned to allow light to be transmitted therethrough, or the electrode may comprise a transparent conductor such as indium tin oxide (ITO). In other variations, both the first and second electrodes of the device may be disposed on a rear side of the device, e.g., so that solar radiation need not pass through an electrode to be incident on an absorbing layer.

Any of the nanostructures, any of the nanoparticles, and any combination of nanostructures and nanoparticles as described herein may be used in these devices. For example, a distribution of a size and/or shape of the metal or metal alloy nanoparticles disposed on the mat of nanostructures may be varied to tune an absorption of the mat, e.g., to extend the absorption of the device relative to that of the photovoltaic panel without the mat. For example, a width and/or peak of a size and/or shape distribution of the nanoparticles may be adjusted to extend the absorption of the device to a visible, near infrared, or infrared wavelength. In other variations, a depth of the mat may be adjusted to tune an absorption of the mat.

Methods for making photovoltaic devices are disclosed herein. These methods comprise electrically connecting a bottom side of a mat to a semiconducting substrate (e.g., silicon or doped silicon), where the semiconducting substrate is in electrical contact with the first electrode, and electrically connecting a top side of the mat to a second electrode such that current flows between the first and second electrodes when the mat and/or the semiconducting substrate is illuminated with solar radiation. A mat used in these methods comprises a plurality of nanostructures (e.g., substantially disordered nanostructures) with metal or metal alloy nanoparticles disposed thereon. The methods may utilize a mat that is sandwiched between the first and second electrodes. In certain variations, the first and second electrodes may each be disposed on a back side of the device.

Some variations of these methods may comprise controlling a size and/or shape distribution of the nanoparticles to tune the absorption of the photovoltaic device. For example, the methods may comprise controlling a size and/or shape distribution of the nanoparticles so as to red-shift the absorption of the photovoltaic device relative to that of the silicon substrate, e.g., to visible wavelengths, near infrared wavelengths or infrared wavelengths.

Provided herein are solar energy capture device functional units. The units comprise an electrode substrate, a mat of semiconductor nanostructures attached to the electrode substrate comprising a plurality of semiconductor nanostructures oriented in a generally random manner, a first metal nanoparticle having a first diameter attached to the mat of semiconductor nanostructures, and a second metal nanoparticle having a second diameter attached to the mat of semiconductor nanostructures, wherein the first and second diameter are not equal. In certain units, the mat of semiconductor nanostructures may have a width, depth, or thickness of about 30 microns to about 10,000 microns. The solar energy capture device units in some instances may comprise a current storage device or a current load device. Some variations of the solar energy capture device functional units comprise a first electrode that functions as a cathode, and an electrolyte media in contact with the mat of semiconductor nanostructures and the first electrode. Certain variations of the solar energy capture device functional units comprise an another electrode substrate, wherein the mat of semiconductor nanostructures is attached to the another electrode substrate. The semiconductor nanostructures of the plurality of semiconductor nanostructures may be selected from the group consisting of ZnO, SnO₂, In₂O₃, Al₂O₃, TiO₂, SiC, and GaN semiconductor nanostructures. In the device functional units, the plurality of semiconductor nanostructures may comprise a plurality of nanostructures (e.g., nanowires, nanosprings, nanorods, or nanotubes) each having cross-sectional diameters of about 1 nm to about 1000 nm. In some device functional units, the first and second metal nanoparticles may be each independently selected from the group consisting of Au, Ag, Cu, Pt, Pd, and Ni metal or metal alloy nanoparticles. The first and second metal nanoparticles may have any suitable dimension (e.g., cross-sectional dimensions such as diameter or radius) but in some instances the first and second metal nanoparticles may have cross-sectional dimensions of about 0.5 nm to about 1000 nm. In some variations of device functional units, the plurality of semiconductor nanostructures may comprise a first set of nanostructures oriented in a first direction and a second set of nanostructures oriented in a second direction, wherein the second direction is not parallel or orthogonal to the first direction. Thus, solar energy capture devices or systems are disclosed herein that comprise two or more solar energy capture device functional units as described above.

### BRIEF DESCRIPTION OF DRAWING FIGURES

The present application can be understood by reference to the following description taken in conjunction with the accompanying drawing figures, in which like parts may be referred to by like numerals.

FIG. 1A illustrates an exemplary electrode substrate with nanostructures disposed on the electrode substrate and metal or metal alloy nanoparticles disposed on the nanostructures.

FIG. 1B is a scanning electron microscope (SEM) image of an example of a mat of nanostructures and metal nanoparticles disposed on the nanostructures; the scale bar equals 1 micron in length.

FIGS. 1C-1E illustrate various examples of nanostructures in cross-section.

FIG. 2 illustrates an exemplary Grätzel-type solar energy capture device comprising a mat of nanostructures and metal or metal alloy nanoparticles disposed on the nanostructures.

FIG. 3 illustrates an exemplary semiconductor-type solar energy capture device comprising a mat of nanostructures and metal or metal alloy nanoparticles disposed on the nanostructures.

FIG. 4 illustrates an exemplary array of semiconductor-type solar energy capture devices.

FIG. 5 illustrates an exemplary array of Grätzel-type solar energy capture devices.

FIGS. 6A and 6B illustrate exemplary devices that may utilize existing photovoltaic solar cells or photovoltaic solar panels.

FIG. 7 shows the absorption profile of an exemplary Ag/Teflon nanocomposite.

FIG. 8 provides a transmission electron microscope (TEM) image of an exemplary Ag/Teflon nanocomposite.

FIGS. 9(a)-9(c) provides a set of TEM images and corresponding histograms showing particle diameter distributions for exemplary Au nanoparticles deposited on nanowires at varying deposition temperatures.

FIG. 10 illustrates an exemplary schematic for a solar energy capture device comprising GaN nanowires.

FIG. 11 provides absorption curves for two examples of GaN nanowires having gold nanoparticles deposited thereon, wherein a distribution of the size and shape of the nanoparticles between the two examples is different.

### DETAILED DESCRIPTION

Despite an increasingly voluminous body of work aimed at the production of highly efficient, cheaply manufactured solar cells, single crystal Si remains the most efficient of the traditional solar cell types. The Carnot limit on the conversion of sunlight to electricity is about 95% as opposed to the theoretical upper limit of about 33% for a Si solar cell. This suggests that the performance of solar cells could be improved approximately 2-3 times if different concepts were used to produce a third generation of high efficiency, low-cost solar cell technologies. A variety of advanced approaches to next generation solar cells are currently under investigation. Among the many approaches under exploration is the implementation of nano-scale structures within solar cells.

Due to their extraordinary photochemical properties and electronic structure similarities to their bulk analogues, semiconductor nanoparticles (e.g., quantum dots, QDs) have been an emergent area of focus within the development of next generation solar cells. Among the primary advantages provided by QDs is the possibility to modulate the band gap of the QD through control of either the particle diameter or composition. QDs have been incorporated into a QD/porphyrin thin film deposited on the surface of a conductive material (see, e.g., U.S. patent application Ser. No. 11/394,560, which is incorporated by reference herein in its entirety), sandwiched between semiconductors of differing morphologies (see, e.g., U.S. patent application Ser. No. 11/484,778, which is incorporated by reference herein in its entirety), and used as a fluorescent material for converting high energy photons to low energy photons that can be utilized by the energy conversion component within a solar cell (see, e.g., U.S. patent application Ser. No. 11/347,681, which is incorporated by reference herein in its entirety).

In parallel, many have been evaluating the functionality of other types of nanostructures within solar cell applications (see, e.g., K. Catchpole, Phil Trans R. Soc., 364, 3493 (2006), which is incorporated by reference herein in its entirety). For example, Kamat et al., have evaluated the use of carbon nanotubes integrated within a TiO₂ semiconductor nanoparticle matrix for enhanced photoelectron capture and transport (see, e.g., P. V. Kamat, et al., Nano Letters 7, 676 (2007), which is incorporated by reference herein in its entirety). Lawandy describes a solar cell wherein metal nanoparticles are integrated within a matrix of TiO₂ nanocrystals, wherein metal particles are operable to enhance the light absorption by the sensitizer dye in order to increase the efficiency of charge injection by a sensitizer (see, e.g., U.S. patent application Ser. No. 11/104,873, which is incorporated by reference herein in its entirety).

Law et al. disclosed a solar cell wherein organic sensitizer molecules were adsorbed on an ordered array of ZnO nanowires (see, e.g., M. Law et al., Nature Materials 4, 455 (2005), which is incorporated by reference herein in its entirety). There, the ZnO nanowire scaffold provided an enhanced surface area relative to the thick films of TiO₂, SnO₂ and ZnO nanoparticles, which are more typical to this class of sensitized solar cells. However, despite the enhanced surface area afforded by the ordered nanostructure array, only modest photoefficencies were realized.

A yet more recent example is provided by Leschkies et al., which disclosed a QD-sensitized solar cell composed of an ordered ZnO nanowire array, wherein the nanowires extend roughly 10 microns from the surface and employ surface modified QDs as a sensitizer (see, e.g., K. S. Leschkies et al., Nano Letters 7, 1793 (2007), which is incorporated by reference herein in its entirety). In this approach, the ZnO forms a type II heterojunction with the semiconductor CdSe QD. Thus, photoexcitation of the QD generates an excited electron (exciton) within the QD, which lies above the conduction band edge of the ZnO, thereby providing a mechanism for the generation of photocurrent. Notable limitations however derive from the limited stability and oxygen sensitivity of the QD sensitizer. Moreover, the feasibility of integrating a range of QD sizes and compositions is questionable given the current state of the art.

There remains a need for highly efficient, cheaply produced solar cell designs for increasing photon capture and photocurrent generation. The ability of a solar cell to capture a broad component of the solar spectrum is a fundamental limitation of current designs. It is estimated that 70% of the efficiency loss observed in present day, single crystal silicon solar cells derives from the narrow nature of the Si band gap; low energy photons do not generate photocurrent while much of the energy from the high energy photons is lost via conversion to heat. While recent implementations employing QDs in sensitized solar cells provide a potential remedy to compensate for these losses, solar cells employing multiple types of QDs pose many technical challenges and thus have yet to be realized in the art.

The use of metal nanoparticles as light harvesting agents provides an alternative route for near complete solar energy capture. MNPs disposed on a semiconductor substrate provides mechanisms to modulate the absorptive properties of the substrate. Unlike in QD implementations, the elemental composition of a MNP can remain static while still capturing a broad segment of the solar spectrum, e.g., the complete solar spectrum, thereby enabling a streamlined device manufacturing process. Moreover, the physical properties associated with the absorptive event may differ; in a QD implementation there exists a direct electron transfer event from the exciton on the QD into the conduction band of the semiconductor substrate. Whereas MNP absorption of a photon results in a surface plasmon resonance formation that may result in a direct electron transfer into the conduction band of the semiconductor substrate or a perturbation of the electronic structure of the semiconductor, enabling photoinduced current-flow.

The use of MNPs on a semiconductor substrate provides a novel type of solar cell that can operate through one or both of the standard photovoltaic mechanisms: a Grätzel-type cell wherein an electron is injected into the conduction band of a semiconductor substrate, and/or a typical semiconductor cell, wherein the photocurrent is generated via electron injection and/or through photon induced exciton formation and conduction.

A common element of a device for solar energy capture utilizing nanostructures is an appropriate cell configuration that can provide increased absorption, e.g., via total or near total internal reflection of incident radiation (e.g., among the nanostructures). When incident radiation experiences total or near total internal reflection in a device, losses may be reduced, such that the number of photons absorbed by the photo-responsive media is increased. Although in some variations a photo-responsive layer used in a solar cell may have a thickness of about 10 to about 20 microns extending from a substrate surface, in other variations, a photo-responsive layer in some variations may be thicker, e.g., so that photon absorption occurs at depths beyond about 10 or about 20 micron range extending from a substrate surface. Further, in some variations, it may be desired that an absorptive surface be substantially non-normal to incident light. In the latter two instances, the increased path length through a photoresponsive medium may allow for increased photon absorption, which may, in turn, result in increased efficiency. For example, depositing a range of particle sizes and shapes on a disordered mat of nanostructures provides broader spectral coverage and improves the light capture properties of the nano-enabled cell. Thus, appropriate orientations of the nanostructured mats and judicious choice of the substrate material is important for nano-enabled photovoltaics.

Grätzel-type solar cells operate through an electron transfer cycle wherein a light harvesting component (typically a molecular chromophore), upon photoexcitation, transfers an electron to the conduction band of a semiconductor substrate (typically nanoporous TiO₂). The circuit is completed via the redox reaction of an electrolyte solution in contact with the chromophore and a cathode. Herein a solar cell structure is proposed wherein MNPs are used as light harvesting components and operate to transfer an electron into the conduction band of a semiconductor nanostructure upon absorption of a photon. In addition to the advantages imparted by MNPs of varied size and shape, which may provide an absorptive profile overlapping with a broad segment of the solar spectrum or even mimicking the solar spectrum, the nanostructured mat (e.g., disordered nanostructured mat) provides scaffolding that can offer facile diffusion of the redox carriers essential to the function of the Grätzel-type solar cell.

Traditional semiconductor solar cells operate on a mechanism involving photon-induced charge mobility between two semiconductor regions (e.g., layers) of differing types. Within such operation, the semiconductor itself acts to capture photons and the resultant exciton provides charge mobility between the two semiconductor regions (e.g., layers). The circuit is completed through an external electrical connection between the two semiconductor regions. Herein a solar cell structure is proposed wherein a MNP, disposed upon a nanostructured semiconductor scaffolding is situated and electrically connected between two semiconducting electrode substrates, the two electrode substrates comprising semiconductor regions of differing types. While a semiconductor region may act as a photon capture in such implementations, the MNP also acts as a photon capture mechanism, thereby trapping a higher percentage of the incident photons. The photon incident on the MNP results in the formation of plasmons which can then influence the charge mobility properties of the exciton formed within the semiconductor regions.

Other solar cells are disclosed. These cells comprise first and second electrodes. A mat comprising a plurality of semiconducting nanostructures (e.g., substantially disordered nanostructures) is electrically connected between the first and second electrodes. A distribution of metal or metal alloy nanoparticles is disposed on the nanostructures in the mat. Upon absorption of a photon, a metal or metal alloy nanoparticle may inject an electron into the conduction band of the semiconducting nanostructure on which it is disposed. The electron then may travel between the first and second electrodes so as to generate a current.

Solar cells built on nanostructures, e.g., one-dimensional nanostructures, such as nanowires and nanosprings, and hierarchical architectures are described herein.

The following description sets forth numerous exemplary configurations, parameters, and the like. It should be recognized, however, that such description is not intended as a limitation on the scope of the present disclosure, but is instead provided as a description of exemplary embodiments.

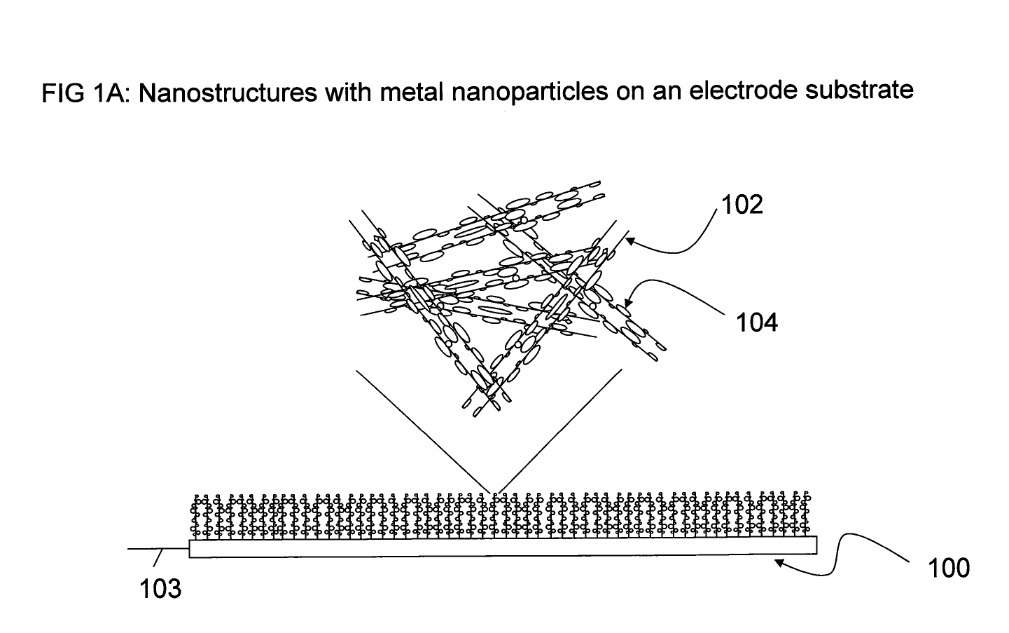

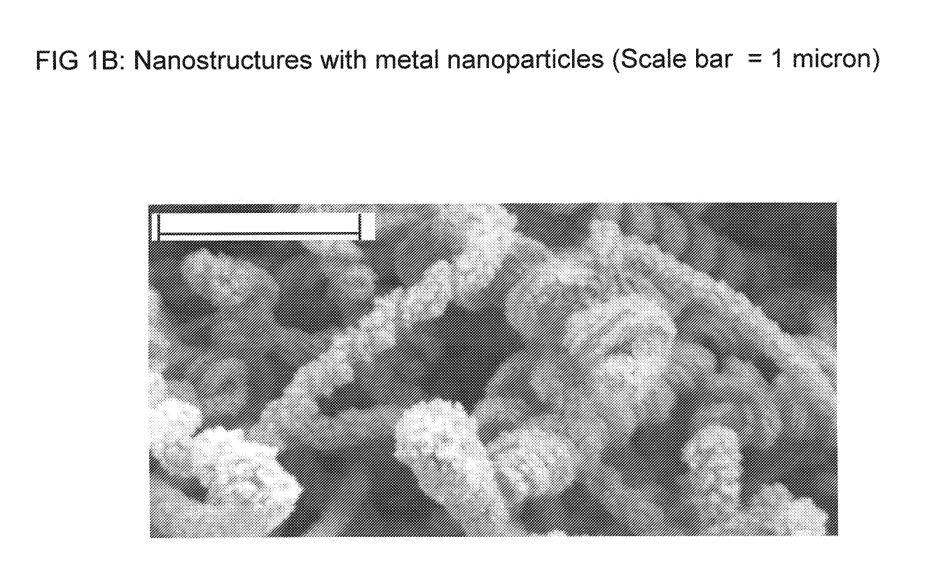

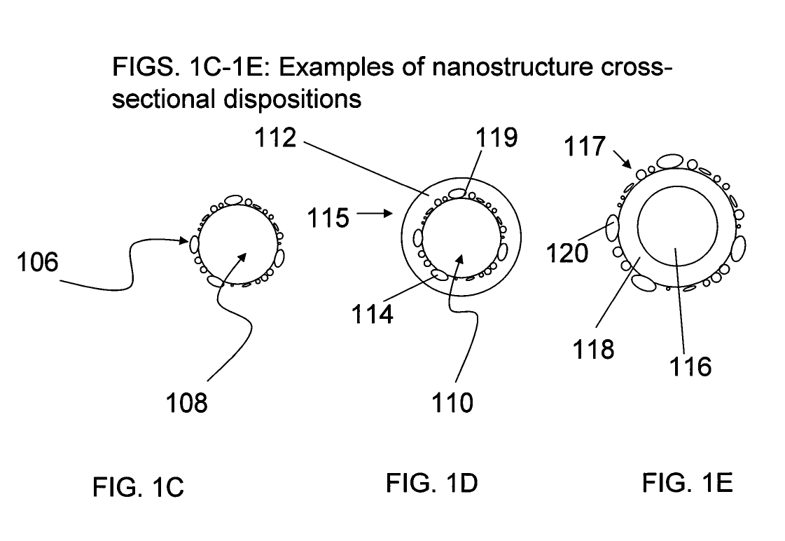

In one embodiment, with reference to FIG. 1A, a functional unit of the solar cell is comprised of a semiconducting and/or conductive electrode substrate 100 with a contiguous (e.g., disordered) mat of semiconductor nanostructures 102. Although the nanostructures are illustrated as rod-like for ease of illustration, it should be understood that nanostructures may comprise other structures, e.g., nanorods, nanowires, nanosprings, nanotubes, or combinations thereof. Metal or metal alloy nanoparticles 104 of varying size, shape and/or aspect ratio are deposited on the nanostructures, or as will be described in more detail, within the nanostructure. The nanostructures are disposed on, e.g., appended to, and in electrical contact with at least one surface of the electrode substrate 100. As used herein, nanostructures may refer to one-dimensional (e.g., having two dimensions on a nanoscale) nanoconstructs and nanoparticles may refer to zero-dimensional (e.g., having three dimensions on a nanoscale) nanoconstructs. Electrode substrate 100 is electrically connected via lead 103 to a load and/or a charge storage device (not shown) operable to store and/or utilize the generated photocurrent. The specific nature of how the circuit is completed may depend on the operational mode of the cell.

Methods to produce the semiconductor nanostructures are described in International Patent Publication WO 2007/002369, published Jan. 4, 2007, which is hereby incorporated by reference, in its entirety. In general, the mat of nanostructures may be grown directly onto a conductive or semiconducting electrode substrate, e.g., using the methods described in International Patent Publication WO 2007/002369.

The semiconducting nanostructures used in the devices may comprise an insulator (e.g., silica (SiO₂ or SiOₓ)) coated with a semiconducting coating (e.g., semiconducting nanoparticles such as ZnO, SnO₂, In₂O₃, TiO₂, or a semiconductor such as Si, Ge, GaN, GaAs, InP, InN or SiC. In some variations, a mat of nanostructures on a conducting or semiconducting electrode substrate may be formed by pre-treating the substrate by depositing a thin film catalyst on the substrate, heating the pre-treated substrate together with gaseous, liquid, and/or solid nanostructure precursor material or materials, and then cooling slowly under a relatively constant flow of gas to room temperature. If more than one precursor material is used, the precursor materials may be added in a serial or parallel manner.

The concentration of precursor material(s) and/or heating time of the pretreated substrate together with the precursor material(s) may be varied to adjust properties of the resultant mat of nanostructures (e.g., mat thickness and/or nanostructure density). Typical heating times are from about 15 minutes to about 60 minutes. Molecular or elemental precursors that exist as gases or low boiling liquids or solids may be used so that processing temperatures as low as about 350° C. may be used. The processing temperature may be sufficiently high for the thin film catalyst to melt, and for the molecular or elemental precursor to decompose into the desired components.

The thin film catalyst may be applied to the substrate using any suitable method. For example, thin films of metal or metal alloy catalysts may be applied using plating, chemical vapor deposition, plasma enhanced chemical vapor deposition, thermal evaporation, molecular beam epitaxy, electron beam evaporation, pulsed laser deposition, sputtering, and combinations thereof. In general, the thin catalyst film may be applied as a relatively uniform distribution (e.g., a contiguous or nearly contiguous uniform layer) to allow for relatively uniform growth of nanostructures. The thickness of the thin film catalyst may be varied to tune properties of the resultant mat of nanostructures (e.g., a thickness of the mat and/or a density of the nanostructures). In some variations, the thickness of the thin film catalyst may be from about 5 nm to about 200 nm. Non-limiting examples of materials that may be used as a thin film catalyst include Au, Ag, Fe, FeB, NiB, Fe₃B and Ni₃B. In some variations, the thin film catalyst layer may be formed as a patterned layer on the substrate (e.g., through the use of masking and/or lithography) to result in a correspondingly patterned mat of nano structures. If a mask is used to pattern the catalytic thin film, the mask may be removed before or after growth of the nanostructures from the catalytic thin film. After a thin film catalyst layer has been applied to the substrate, the substrate is heated, in some cases so that the catalyst layer melts to form a liquid, and one or more nanostructure precursor materials are introduced in gaseous form so that they can diffuse into the molten catalytic material to begin catalytic growth of the nanostructures.

In some variations of these processes, a pre-treated substrate may be heated together in a chamber at a relatively constant temperature to generate and maintain a vapor pressure of a nanostructure precursor element. In these variations, non-limiting examples of nanostructure precursor materials include SiH₄, SiH(CH₃)₃, SiCl₄, Si(CH₃)₄, GeH₄, GeCl₄, SbH₃, AlR₃, where R may for example be a hydrocarbon.

In other variations of these processes, a pre-treated substrate may be heated in a chamber together with a solid elemental nanostructure precursor at a relatively constant temperature that is sufficient to generate and maintain a vapor pressure of the nanostructure precursor element. In these variations, non-limiting examples of the solid elemental nanostructure precursors include C, Si, Ga, B, Al, Zr and In. In some of these variations, a second nanostructure precursor may be added into heated chamber, e.g., by introducing a flow or filling the chamber to a static pressure. Non-limiting examples of the second nanostructure precursor include CO₂, CO, NO and NO₂.

In still other variations, a pre-treated substrate may be heated in a chamber to a set temperature at least about 100° C., and a first nanostructure precursor material may be introduced into the chamber through a gas flow while the chamber is heated to the set temperature. After the chamber has reached the set temperature, the temperature may be held relatively constant at the set temperature, and a second nanostructure precursor material may be flowed into the chamber. In these variations, non-limiting examples of the first and/or second nanostructure precursor materials include SiH₄, SiH(CH₃)₃, SiCl₄, Si(CH₃)₄, GeH₄, GeCl₄, SbH₃, AlR₃ (where R is for example a hydrocarbon group), CO₂, CO, NO, NO₂, N₂, O₂, and Cl₂.

For example, to make a mat comprising helical silica nanostructures, a substrate capable of withstanding at least about 350° C. for about 15 to 60 minutes may be pre-treated by sputtering a thin, uniform layer of Au on the substrate (e.g., a layer about 15 nm to about 90 nm thick). To achieve the desired Au thickness, the substrate may be placed into a sputtering chamber at about 60 mTorr, and an Au deposition rate of about 10 nm/min may be used while maintaining a constant O₂ rate during deposition. The substrate that has been pre-treated with Au may be placed in a flow furnace, e.g., a standard tubular flow furnace that is operated at atmospheric pressure. A set temperature in the range of about 350° C. to about 1050° C., or even higher, may be selected depending on the substrate used. During an initial warm up period in which the furnace is heated to the set temperature, a 1 to 100 standard liters per minute (slm) flow of SiH(CH₃)₃ gas is introduced into the furnace for about 10 seconds to about 180 seconds, and then turned off. After the flow of SiH(CH₃)₃ is terminated, pure O₂ may be flowed through the furnace at a rate of about 1 to 100 slm. The furnace is then held at the set temperature for about 15 to about 60 minutes, depending on the desired properties of the mesh of silica (SiO₂ or SiOₓ) nanostructures.

A range of densities of nanostructures on the substrate may be made with the methods described here. The density of nanostructures on the substrate may be varied by varying the thickness of the thin film catalyst deposited on the substrate. If the thin film catalyst layer is relatively thick (e.g., 30 nm or thicker), the nanostructures may be very densely packed with nanostructures comprising groups of intertwined and/or entangled nanostructures, e.g., nanosprings, or a combination of nanostructures. A relatively thin catalyst film (e.g., about 10 nm or thinner) may result in nanostructures that may be widely spaced apart, e.g., about 1 μM apart or even farther). For example, an areal density of nanostructures on the substrate of about 5×10⁷ nanostructures per square cm to about 1×10¹¹ nanostructures per square cm may be achieved.

In some variations, multiple layers of nanostructures (e.g., nanosprings) can be formed by depositing a catalyst layer onto an existing mat or mesh, whereby nanostructures are grown on top of the existing mat or mesh by the previously described process. This catalyst may, for example, be nanoparticles (e.g., gold nanoparticles) that have been coated onto the nanostructures in the existing mat. In some variations, each layer in a mesh or mat may have a depth of about 10 μm, and multiple layers may be built up to provide a mesh or mat that has a depth of about 20 μm, about 30 μm, about 50 μm, about 80 μm, about 100 μm, or even thicker, e.g., about 200 μm, about 300 μm, about 400 μm, or about 500 μm.

As described above, metal or metal alloy nanoparticles are disposed on the nanostructures in the mats. The nanoparticles may have a size distribution and/or a shape distribution that is selected to tune an absorption spectrum of a solar cell utilizing such mats. That is, a width of a particle size distribution, a peak of a particle size distribution, or a width and/or peak of a particle shape distribution (including aspect ratio) may be adjusted so that the absorption spectrum of that population of nanoparticles disposed on a mat overlaps with a desired part of the solar radiation spectrum. For example, a distribution of nanoparticles may be selected so that, together with a silicon substrate, a solar cell can absorb over wavelengths from about 300 nm to about 2500 nm, e.g., from about 500 nm to about 2000 nm, or from about 300 nm to about 1500 nm. In some cases, a distribution of nanoparticles can be selected specifically to augment the absorption of the electrode substrate by increasing absorption of the solar cell in visible, near infrared, or infrared wavelengths, e.g., at wavelengths of about 500 nm or higher, about 550 nm or higher, about 600 nm or higher, about 650 nm or longer, about 700 nm or longer, about 750 nm or longer, about 800 nm or longer, about 850 nm or longer, about 900 nm or longer, about 950 nm or longer, about 1000 nm or longer, about 1100 nm or longer, about 1200 nm or longer, about 1300 nm or longer, about 1400 nm or longer, about 1500 nm or longer, about 1600 nm or longer, about 1700 nm or longer, about 1800 nm or longer, about 1900 nm or longer, or about 2000 nm or longer.

The nanostructures may be metallized or coated with MNPs with a coverage that is sufficient to impart the desired absorption properties to a mat. To take advantage of the high surface area provided by the nanostructures, the MNPs may coat the nanostructures uniformly to provide a contiguous conductive surface, e.g., over a majority of the surface area of the nanostructures forming the mat. Further, the MNPs may have small enough dimensions that they may coat individual nanostructures in a relatively conformal manner, e.g., without substantially filling or blocking intra-nanostructure spaces or inter-nanostructure spaces. For example, the MNPs may form a conformal coating of about 30 nm, about 50 nm, about 60 nm, about 70 nm, about 80 nm, about 90 nm, or about 100 nm thick. Thus, the nanoparticle coating may result in a dimension of a coated nanostructure increasing by a factor of about 2, about 3, about 4, or in some case, an even higher factor, as compared to an uncoated nanostructure. In other variations, the MNPs may not form a contiguous coating on the nanostructures, and may instead be applied as relatively separated particles or groups of particles.

The metal or metal alloy nanoparticles may have any suitable composition. For example, metal or metal alloy nanoparticles comprising gold, silver, copper, platinum, nickel, palladium, or a combination thereof, may be used.

The metal or metal alloy nanoparticles may be applied to the nanostructures using any suitable method. For example, the nanoparticles may be applied using atomic layer deposition (ALD), chemical vapor deposition (CVD), or plasma-enhanced chemical vapor deposition (PECVD). In general, the nanoparticles may have an average diameter of about 100 nm or less, about 50 nm or less, about 40 nm or less, about 30 nm or less, about 20 nm or less, or about 10 nm or less, or even smaller, about 5 nm or less, e.g., about 4 nm, about 3 nm, or about 2 nm. Further, as describe above, an average nanoparticle dimension (e.g., diameter) and/or a standard deviation of the distribution of a nanoparticle dimension applied to the nanostructures may be selected to tune an absorption spectrum of the mat. In some cases, more than one average size nanoparticle may be applied to a mat, e.g., in multiple applications. For example, a first application may apply relatively large particle sizes, e.g., about 5 to about 50 nm, and the second application may apply relatively small particles sizes, e.g., less than about 10 nm. A broad distribution of nanoparticle sizes may increase the width of the absorption spectrum, and make for greater packing of the nanoparticles, e.g., where smaller nanoparticles may fill in voids or gaps in the coverage by the relatively large nanoparticles.

To tune the absorption spectrum of the mats, the metal or metal alloy nanoparticles may be deposited or grown on the nanostructures in such a manner as to control an average nanoparticle size, size distribution, average particle shape (e.g., aspect ratio) and/or shape distribution (e.g., aspect ratio distribution). In some variations, the nanostructures may be metallized in a parallel plate PECVD chamber operated about 13.56 MHz. The chamber volume is about 1 cubic meter. The parallel plates are 3″ in diameter and separated by 1.5″. A nanoparticle precursor and carrier gas (e.g., argon) mixture may be introduced into the chamber from a nozzle in the center of the anode, and the sample holder may serve as a ground plate. The temperature and the pressure of the deposition process may be varied to vary the average nanoparticle size and particle size distribution. PECVD may be used to grow a variety of conductive or semiconducting nanoparticles, with non-limiting examples including gold, nickel and platinum. For example, dimethyl(acetylacetonate)gold(III) may be used as a precursor for gold nanoparticles, bis(cyclopentadienyl)nickel may be used as a precursor for nickel nanoparticles, and (trimethyl)methylcyclopentadienylplatinum(IV) may be used as a precursor for platinum nanoparticles. Each of these precursors is commercially available from Strem Chemicals, Newburyport, Mass.

Gold nanoparticles having small average particles sizes and narrow particle size distributions may be produced on nanostructures (e.g., silica nanostructure) using PECVD at pressures between about 17 Pa and 67 Pa, and at substrate temperatures of about 573K to about 873K. For example, gold nanoparticles having an average particle diameter of about 5 nm, with a standard deviation of 1 nm may be deposited on silica nanostructures using PECVD with a total chamber pressure of about 17 Pa, a substrate temperature of 573K, a precursor material of dimethyl(acetylacetonate)gold(III), and argon as a carrier gas. Gold nanoparticles having an average diameter of 7 nm with a standard deviation of 2 nm may be similarly produced, except with a total chamber pressure of 72 Pa and a substrate temperature of 723K. Gold nanoparticles having an average diameter of 9 nm with a standard deviation of 3 nm may be produced with a total chamber pressure of 17 Pa and a substrate temperature of 873K. Additional examples of gold nanoparticle distributions that may be formed on silica nanostructures are described in A. D. LaLonde et al., “Controlled Growth of Gold Nanoparticles on Silica Nanowires,” Journal of Materials Research, 20 3021 (2005), which is hereby incorporated by reference in its entirety. Other metal or metal alloy nanoparticles may be deposited onto nanostructures using PECVD or CVD using starting materials and deposition conditions known in the art.

Utilizing the methods disclosed therein, various constructs of nanostructures and nanoparticles are contemplated. For example referring now to FIG. 1C, in some variations, metal or metal alloy nanoparticles 106 may be disposed on an external surface of a semiconducting nanostructure 108. Referring to FIG. 1D, an additional layer of complexity may be introduced wherein the nanostructure 115 has a core-shell type structure and the metal or metal alloy nanoparticles are deposited on the surface of a core nanostructure 110 that is subsequently at least partially covered by or at least partially encapsulated with an additional layer of material (a shell) 112. Further, as illustrated in FIG. 1E, another variation of a nanostructure comprising a core-shell type structure is shown. There, nanostructure 117 comprises a core 116 that is subsequently at least partially covered by or at least partially encapsulated with a shell 118. In this variation, the metal or metal alloy nanoparticles are disposed on the shell 118.

For variations in which the nanostructure has a core-shell type structure, e.g., those illustrated in FIGS. 1D and 1E, the shell and the core may have the same or different composition. For example, the core may comprise an insulator (e.g., silica) and the shell may comprise a semiconductor (which may be formed from or comprise semiconducting nanoparticles). Alternatively the core may comprise a semiconductor and the shell may comprise an insulator (e.g., silica). In some variations, each of the core and the shell may be semiconducting. In certain of these variations, the materials used in the core and in the shell may have different intrinsic dopant characteristics for the core and the shell. Thus, for example, one of the core and shell may comprise an n-type semiconductor material, and the other of the core and shell may comprise a p-type semiconductor, and a p-n junction may be formed at the interface between the core and the shell. In certain variations, metal or metal alloy nanoparticles may be placed at or near this interface. For example, referring again to FIG. 1D, an n-type semiconductor material may be used for core 110 and a p-type semiconductor material may be used for shell 112 generate a p-n junction at the interface 119, which in this example is co-localized with the zero dimensional nanoparticles 106. Referring again to FIG. 1E, one of the core 116 and the shell 118 of nanostructure 117 may comprise a p-type and the other of the core 116 and the shell 118 may comprise an n-type semiconductor. Alternatively, a nanostructure 117 may comprise an insulating core 116 (e.g., silica) and a semiconducting shell 118. As indicated above, a semiconducting shell may be formed by depositing or otherwise growing semiconducting nanoparticles on the core. For example, nanostructures may be used that comprise ZnO nanoparticles deposited on silica nanostructures.

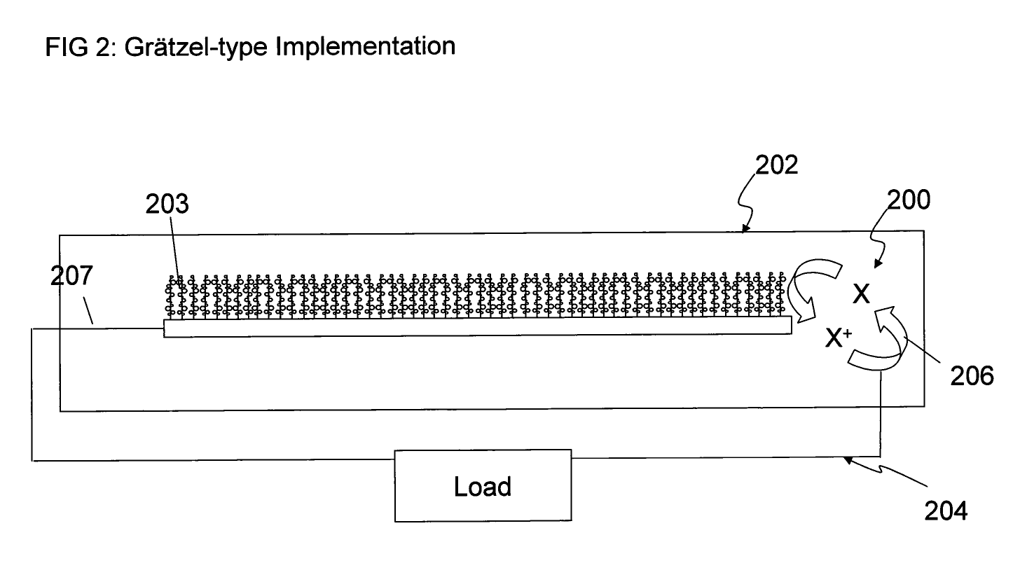

In an embodiment depicted in FIG. 2, MNPs are deposited on an external surface of a mat comprising nanostructures, and the cell is operable in a Grätzel-type implementation of a solar cell. That is, an electrolyte (electron carrier) 200 housed within the solar cell 202 is in contact with the semiconducting nanostructures 203. As a photon is absorbed by a MNP 205 disposed on nanostructures 203, an electron can be injected into the conduction band of the semiconducting nanostructures 203 on the anode 207. The electrolyte 200 can then replace the electron in the MNP, leading to an electron-deficient electrolyte species (X⁺). The electron deficient electrolyte species can transfer to the counter-electrode (cathode) where current is injected to complete the redox reaction as shown by arrows 206. Thus, the electrolyte is operable to shuttle electrons from at least one cathode 204, within the cell.

In these Grätzel-type solar cells, a top electrode is generally transparent, and a bottom electrode is generally opaque. Thus, a top transparent electrode may comprise the mat comprising MNPs, and a bottom opaque electrode may comprise any suitable electrode type. In certain variations, both electrodes of a Grätzel-type solar cell may comprise a mat of nanostructures. In those variations, only that mat that is configured to absorb incident solar radiation may comprise MNPs. However, in some variations, both mats may comprise MNPs.

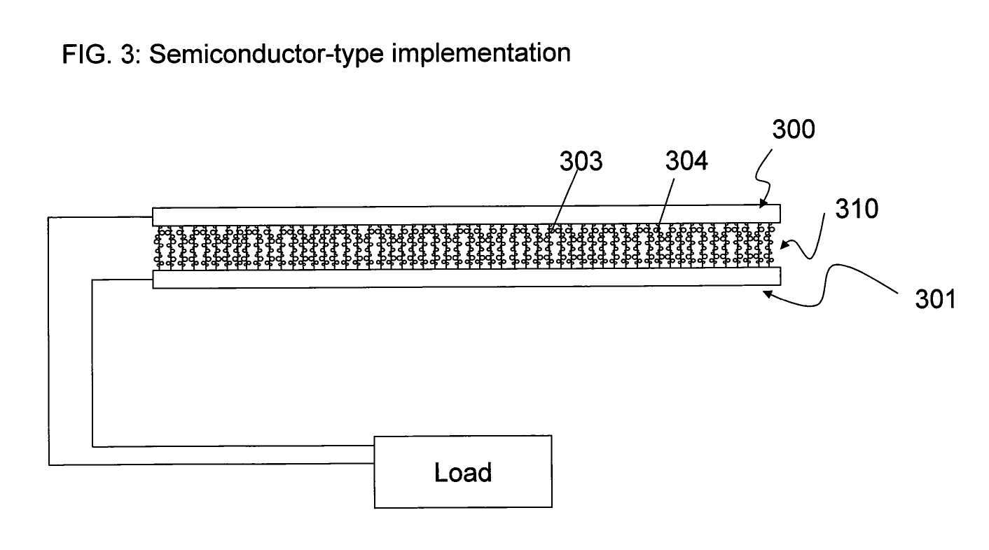

In an embodiment depicted in FIG. 3, MNPs 304 are deposited on or encapsulated within the semiconductor nanostructures 303, and/or the solar cell 310 is operable in a semiconductor-type implementation. That is, the circuit is completed through a direct electrical connection between the first electrode substrate 301 to which nanostructures 303 make electrical contact and a second electrode substrate 300 positioned opposite the first electrode substrate 301. The nanostructures 303 also make electrical contact with second electrode. Thus, the mat 304 comprising nanostructures 303 is disposed between and in electrical contact with the first and second conducting or semiconducting electrode substrates 301 and 300, respectively. As MNPs 304 absorb incident photons, charge carriers are generated in the semiconducting nanostructures. In some variations, a p-n junction in the solar cell, e.g., in a semiconducting nanostructure itself (e.g., between a core and a shell as described above) or between a semiconducting nanostructure and an electrode substrate, or within an electrode substrate, or between two different semiconducting electrode substrates in the solar cell, separates the charge carriers so that a current is generated. Further, in some cases, absorption of a photon by a MNP may lead to direct electron injection into a semiconducting nanostructure. In those variations, the injected electron may flow between the first and second electrodes to generate a current. The electrode substrate 301 on which the nanostructures are disposed, and the nanostructures themselves may absorb solar radiation as well as the MNPs. It should also be noted that although the solar cell 310 is illustrated in FIG. 3 as having a mat sandwiched between two electrodes, other variations are contemplated wherein the mat is electrically connected between two electrodes but is not sandwiched between the electrodes, e.g., two electrodes may be spaced apart in a plane, and a mat may be disposed on the two electrodes.

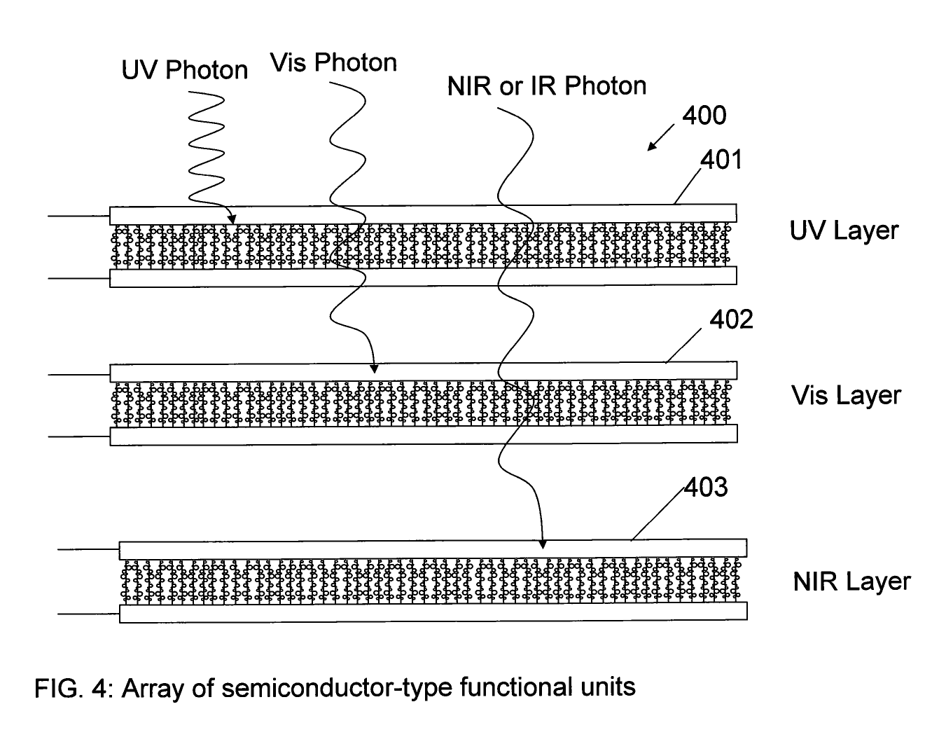

In an embodiment depicted in FIG. 4, a solar energy capture device functional unit is integrated into a larger array comprising of multiple solar energy capture device functional units arranged in a manner operable to increase photon capture. Thus, in the example illustrated in FIG. 4, the array or system 400 comprises three solar energy capture devices. The first solar energy capture device 401 is configured to absorb preferentially in the ultraviolet relative to other devices in the array, the second solar energy capture device 402 is configured to absorb preferentially in the visible relative to other devices in the array, and the third solar energy capture device 403 is configured to absorb preferentially in the infrared relative to other devices in the array. Such a cascade of devices may be configured in any order so as to increase the overall absorption and/or efficiency of the system. In this particular example, solar radiation is first incident on the most ultraviolet absorbing cell, with cells arranged in order of increasing preferential wavelength. However, cells may be arranged in an order reversed compared to that shown in FIG. 4 or may be arranged in any other desired sequence. One or more of the devices in an array such as array 400 could comprise a conventional semiconductor or silicon photovoltaic panel or device rather than a device utilizing semiconductor nanostructures as described herein. In such a multilayer or multi-device arrangement a device utilizing metallized semiconductor nanostructures could be used to selectively increase or tune absorption in the visible, near infrared, or infrared region of the spectrum, e.g., in those spectral regions where absorption by silicon and other semiconductors may be relatively low.

Without being limited by theory, the electrode substrate is operable to transfer current from the site of the electron injection (e.g., in Grätzel-type solar cells) or exciton formation (in traditional implementations, e.g., those involving charge separation across a p-n junction in a semiconductor) to the external current carrying wire and thus has at least one current carrying element in electrical communication operable to draw photogenerated current from the photoactive elements within the functional unit cell (solar cell). In some embodiments, to complete the circuit, a second current carrying element (or set thereof) operable to regenerate the photocurrent drawn from the device is in electrical communication with the electrode substrate.

The electrode substrate may be composed of a conductive, or semiconductive media. Example conductive electrode media include metals or metal alloys wherein the metal is any element generally considered as metallic. A semiconductor electrode may be composed of any elemental, binary, tertiary, quaternary, or higher order elemental compositions possessing the conductive properties consistent with what is generally deemed a semiconductor in the art. In variations where solar radiation must pass through an electrode to reach an absorbing layer, an electrode may be a transparent conducting or semiconducting electrode, or may be patterned (e.g., a patterned metal) to allow partial illumination of the absorbing layer through gaps in the pattern.

The nanostructured mats present on the surface of the electrode substrate may be comprised of nanosprings and/or nanowires, generally ranging in cross-sectional diameter between 1 nanometer and 1000 nanometers. Such structures may be discrete, independent one-dimensional structures, or may be bundled or coiled into larger structures of higher order that also randomly wind through the nanostructured mat. Collectively, the nanostructures form an intertwining mat that does not contain a significant degree of collective order and is generally random (i.e., disordered) in orientation and placement. By generally random, it is understood that the nanostructures of the mat do not exhibit a high degree of spatial periodicity. Further, it is understood that a degree of spatial periodicity may be exhibited. In one embodiment, a disordered mat of about 500 microns in thickness exhibits a degree of spatial periodicity in the space extending from about 1 micron to about 20 microns from a surface of the electrode substrate, with the remaining about 480 to about 499 microns exhibiting a low or non-existent degree of spatial periodicity. In another embodiment the disordered mat exhibits a low degree of spatial periodicity when comparing nanostructures, but may display a degree of order with respect to the crystalline structure of a given nanostructure of the mat.

The resultant nanostructured mat (e.g., disordered nanostructured mat) is between about 10 microns and about 500 microns thick. Without being limited by theory, the thick, disordered mat may provide an improved scaffolding for use in solar cell applications due to the thickness and disorder of the mat that may provide a nanostructured surface that can impart enhanced adsorptive properties and/or enhanced diffusive properties for more facile nanostructure surface modification and/or surface particle regeneration.

The nanostructures may be composed of any elemental, binary, tertiary, quaternary or higher order elemental compositions possessing the conductive properties consistent with what is generally deemed a semiconductor in the art. Particular examples include but are not limited to ZnO, SnO₂, In₂O₃, Al₂O₃, TiO₂, SiC, and GaN nanostructures.

The nanoparticles comprise metal or metal alloy particles ranging in diameter from 0.5 nm to 1000 nm, herein “diameter” is not intended to limit the range of nanoparticle shapes; rather diameter refers to the largest continuous span of material. MNPs may comprise spheres, triangles, pentagons and other similar discrete shapes and/or conglomerates thereof. In the preferred implementation, the MNPs disposed on the nanostructures comprise a range of shapes and sizes. In some variations, the composition of the MNP may comprise a pure metal or metal alloy selected from at least one of the following: Au, Ag, Cu, Pt, Pd, and Ni metal or metal alloy. It is however to be understood that any suitable metal may be employed herein, including but not limited to the transition metals, actinides, lanthanides, main group and alkali earth metals.

Within the solar cell the MNPs are operable to act as the capture agent for the incident solar irradiation. Central to the utility of this implementation is the ability to alter the absorptive properties of the MNPs based upon the structural features of the MNPs. The techniques described herein provide a platform to tailor the structural composition of the MNPs disposed on the nanostructure scaffold to the spectral profile of the solar irradiation, thereby imparting a solar cell with increased solar absorption, e.g., over a desired portion of the solar spectrum.

Within a solar cell, absorption only provides one component of the operability. As is noted above, a central property of both types of solar cells is the ability to convert the light capture event (absorption) into a photocurrent. Most solar cells known in the art can be described in terms of the mechanism for the generation of photocurrent. In traditional semiconductor solar cells, the incident photon elevates an electron into a conduction band of the semiconductor and, due to a bias, the electron is swept through the semiconductor thereby generating current. In the Grätzel-type cells, the incident photon excites a discrete molecular (or semiconductor) body to form an exciton that subsequently injects the electron into the conduction band of a substrate semiconductor thereby generating current. The present invention does not cleanly partition into either of these groups. Due to the unique physical properties of the plasmon formed upon absorption of a photon by a metal nanoparticle, the operable mechanism for the generation of photocurrent can comprise a semiconductor-type and/or a Grätzel-type photocurrent generation. While differing design elements and electrode/cell geometries can be evaluated to best harness the dual properties of this novel type of solar cell, the added flexibility in operable photocurrent generation mechanism affords an advantage of the approach described herein.

When operating in a pure Grätzel-type implementation, the plasmon formed on the MNP generates an excited electron that is injected into the semiconductor nanostructure that is subsequently swept through the semiconductor medium due to the presence of an applied bias. The circuit is completed by an electron carrier within the cell that is in operable communication with both the MNPs and an electrode with an applied voltage. The electron carrier may be any known to the art (I₃ or other molecular agents, electroactive polymer gels, ionic liquids, etc.)

When operating in a pure semiconductor type implementation, the MNPs may be located on or within a semiconductor nanostructure that is disposed, and in electrical communication, between two electrodes. Photons incident on the MNPs cause an oscillation of the electric field in the area surrounding the MNPs that facilitates current flow through the semiconductor nanostructure between the two electrodes. Since this implementation is independent of the electron transfer event between the MNPs and the semiconductor nanostructure surface, accessibility of the MNPs is not an essential component and therefore the MNPs may be encapsulated within the semiconductor nanostructure.

A hybrid mode of operation is also described herein. In such an implementation, the nanostructured mat is disposed, and in electrical communication, between two electrodes. In particular embodiments the electrodes are of differing electrical properties (e.g. an n-type semiconductor and a p-type semiconductor) and the MNP-loaded nanostructured mat resides within the p-n junction. Upon interaction with an incident photon, pluralities of MNP-localized plasmons are formed. Some of the excited MNPs directly inject electrons into the conduction band of the semiconductor nanostructure while some of the plasmons influence the electronic structure of the semiconductor thereby enabling current flow between the n-type and p-type electrode due to the presence of the applied bias. Optionally, the hybrid cell may have an electron carrier in electrical communication with the nanostructures and the electrodes.

It is understood that a range of different solar cell configurations are possible, of which a limited, exemplary subset of potential configurations are presented herein. The most basic element of the cell is a contiguous mat of semiconductor nanostructures with MNPs of varying size, shape and aspect ratio deposited thereon, such hierarchical scaffolding being situated on an electrode substrate, as depicted in FIG. 1. The basic operable unit of the cell may depend on the operable mechanism of the cell, as depicted in FIG. 3 and FIG. 4. As described above, in certain variations, a mat may be in electrical contact with two electrodes, where the electrodes may for example be arranged in a side-by-side planar manner and the mat disposed on or between side-by-side electrodes, or in a stacked manner where the mat is sandwiched between the stacked electrodes. A sandwich-like design for operation in a semiconductor or hybrid type mode wherein the mat of contiguous nanostructures with MNPs is disposed between two electrodes in electrical communication with the nanostructures provides an exemplary embodiment. In a single layer embodiment, the mat of nanostructures with MNPs is disposed on the surface of a first electrode substrate and is in electrical communication with a second electrode operable to regenerate the MNP electrons that are injected into the semiconductor nanostructure.

Additional embodiments are contemplated wherein two electrodes are positioned in a sandwich type configuration, with each electrode having a mat of contiguous one-dimensional nanostructures with at least one of the contiguous mats has zero-dimensional metal nanoparticles of at least one diameter deposited either within or on the surface of the one-dimensional nanostructure. Solar cells of this type preferentially employ one-dimensional nanostructures of differing compositions (i.e., the composition of the contiguous mat on one electrode is of differing composition than that of the contiguous mat disposed on the second electrode). With the two nanostructured mats of differing composition in electrical contact a p-n junction can be formed at the material interface.

The nanostructured mats, while substantially thicker than those commonly employed in the art, may be on the order of e.g., only hundreds of microns thick and still designed to enhance solar capture. Examples include a stacked cell, wherein the absorptive properties can be tailored to the position of the layer, e.g., as depicted in FIG. 4. As depicted, the MNP composition could differ from layer to layer thereby providing an optimal absorptive profile for the photons that will be incident upon the subsequent layers.

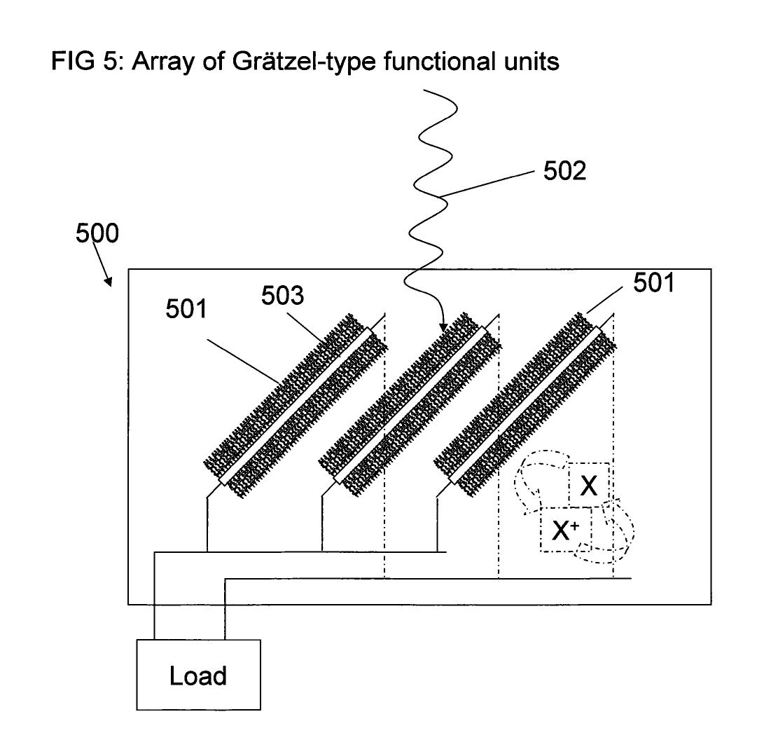

Another example of an array or system comprising multiple cells is illustrated in FIG. 5. In the embodiment illustrated in FIG. 5, the system 500 comprises a set of series-connected Grätzel-type cells 501. In this particular example, orientation of the electrode surfaces 503 at a steep angle relative to the incident photon 502 may provide for enhanced absorption by a cell 501. While not being limited by theory, the steep incident angle may provide at least two advantages. For example, the photon may have a longer path through the nanostructured mat and/or the angle of incidence (e.g. relative to the substrate 502 may be modulated to enhance the internal reflection, allowing for more effective photon capture.

The nanostructured mats might be integrated with any form of existing photovoltaic (PV) device or solar panel in such a way that the total spectral range of photon absorption of the device is increased by the nanostructured mats. For example, nanostructured mats might be integrated with an amorphous silicon PV device (e.g., a device comprising an amorphous thin film of silicon), which has an inherently low efficiency and limited range of spectral absorption. The nanostructured mats might be decorated with absorbing nanoparticles such that the absorption was optimized for energies within the visible, near infrared, or infrared region of the electromagnetic spectrum, which is currently not captured efficiently by most conventional photovoltaic devices using silicon as the absorption medium. Consequently, the range of solar radiation absorbed by the multilayer device is increased.

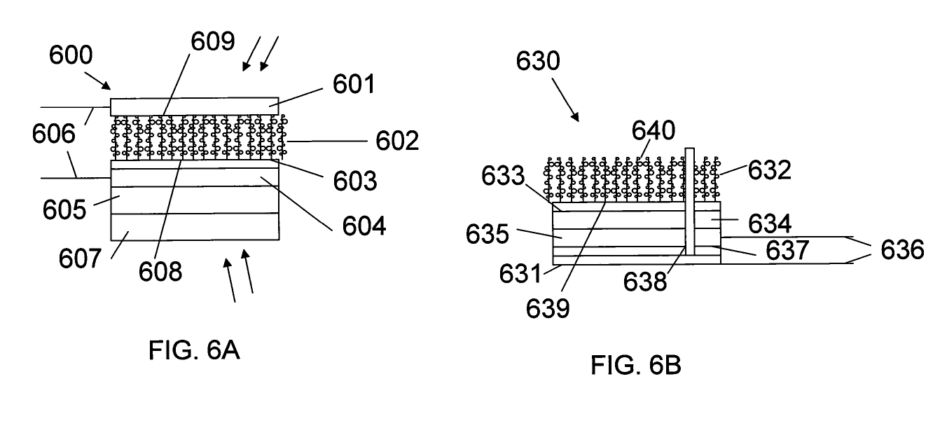

Referring now to FIGS. 6A and 6B, two examples of devices that may incorporate an existing photovoltaic device or solar panel are shown. In FIG. 6A, device 600 comprises a glass substrate 607 upon which a first electrode 605 is disposed, and semiconducting layer 604 (e.g., silicon or doped silicon such as amorphous silicon or polycrystalline silicon) disposed on the electrode 605. The electrode may in some variations comprise indium tin oxide. Optionally, an antireflecting coating 603 may be disposed on the semiconducting layer 604. A nanostructured mat 602 as described herein is disposed on antireflecting coating 603 if present, otherwise directly on the semiconducting layer 604. Thus, a bottom side 608 of the mat 602 is in electrical contact with the first electrode 605 via semiconducting layer 604 and optional antireflecting coating 603. A top side 609 of the mat 602 is placed in electrical contact with a second electrode 601. The second electrode 601 may for example comprise indium tin oxide on a glass substrate, or may comprise a patterned metal layer. As shown by the arrows in FIG. 6A, the device 600 can be illuminated so that the semiconducting layer first receives incident solar radiation and/or the mat first receives solar radiation. Absorption of photons by the semiconducting layer 604 and/or absorption of photons by the MNPs on the mat 602 can lead to charge generation as described above, so that a current can flow between the first electrode 605 and the second electrode 601, and leads 606 may for example be connected to a load or a charge storage device. Of course, an antireflecting coating, if present, may be applied to reduce reflections on an incident surface, and thus if the incident surface changes, the placement of the antireflecting coating may change accordingly.

Referring now to FIG. 6B, another example of a solar energy capture device that may utilize off-the-shelf photovoltaic devices and/or photovoltaic solar panels. In this example, device 630 comprises a second electrode 631 (e.g., indium tin oxide), an insulating layer 637 (e.g., silica or glass) disposed on the second electrode 631, a first electrode 635 (e.g., indium tin oxide) disposed on the insulating layer 637, a semiconducting layer 635 (e.g., silicon or doped silicon such as amorphous silicon or polycrystalline silicon) disposed on the first electrode, and, optionally, an antireflective coating 633 disposed on the semiconducting layer 634. A mat of metallized nanostructures 632 as described herein may be provided on the antireflective coating 633, if present, and otherwise directly on the semiconducting layer 634. Thus a bottom side 639 of the mat 632 is in electrical contact with the first electrode 635 via semiconducting layer 634 and optional antireflecting coating 633. A top side of the mat 640 is in electrical connection with the second electrode using via 638. Thus, in this particular variation, both first and second electrodes are on the same side of the device. Thus device 630 can be illuminated so that the mat receives the first incident solar radiation, without the solar radiation having to pass through an electrode. Of course, device 630 can also be illuminated such that the semiconducting layer 634 receives the first incident solar radiation, e.g., if first electrode 635 and second electrode 631 are sufficiently transparent. Leads 636 are connected to the first electrode 635 and the second electrode 631 so that photocurrent generated in the device 630 may be used to drive a load or charge a charge storage device.

Various methods are also disclosed herein. Methods for generating photocurrents using the nanostructured mats as disclosed above are provided. In addition, methods for making a photovoltaic solar cell are provided.

For example, some methods for generating a photocurrent comprise providing a solar energy capture device as described herein, the device comprising a mat of semiconducting nanostructures (e.g., substantially disordered nanostructures) disposed on and in electrical contact with a conductive or semiconducting first electrode substrate. A plurality of metal or metal alloy nanoparticles is disposed on the nanostructures. The methods comprise irradiating the solar energy capture device with solar radiation so that the metal or metal alloy nanoparticles absorb incident solar radiation to generate charge carriers in the nanostructures to generate a current. The methods may employ any method of generating charge carriers upon absorption of a photon, e.g., electron injection and/or formation of an exciton which is subsequently separated into free charge carriers. The semiconducting nanostructures (e.g., nanowires, nanosprings, nanotubes, nanorods or a combination thereof) and MNPs used in the methods may have any configuration or composition as described herein. Thus, the nanoparticles used in the methods may comprise gold, silver, copper, platinum, nickel, alloys thereof and/or combinations thereof, and/or the nanostructures may comprise ZnO, SnO₂, In₂O₃, Al₂O₃, TiO₂, SiC, GaN, or a combination thereof. Further, at least some of the nanostructures may be primarily composed of a semiconductor (e.g., some nanostructures may be primarily composed of GaN).

In the devices used in the methods, a distribution of the size and/or shape of the nanoparticles may have been used to tune the absorption characteristics of the solar energy capture devices, as described above. For example, a width of a nanoparticle size distribution and/or a peak of the size distribution may be adjusted to expand the absorption spectrum of the solar energy capture device, e.g., to increase absorption at visible, near infrared or infrared wavelengths. In some cases, the methods may comprise adjusting a distribution of aspect ratios of nanoparticles to adjust the absorption spectrum of the solar energy capture devices.

Some methods may employ semiconducting nanostructures that comprise a core disposed at least partially within a shell. In those variations, metal or metal alloy nanoparticles can be disposed on the core and be at least partially covered by the shell and/or the metal or metal alloy nanoparticles can be disposed on the shell. The core may be insulating and the shell may be semiconducting, or the core may be semiconducting and the shell may be insulating. In certain variations, each of the core and the shell can be semiconducting. For example, one of the core and the shell can comprise a p-type semiconductor and the other of the core and the shell can comprise an n-type semiconductor. Thus, an insulating core or shell can comprise silica, and a semiconducting core or shell can comprise GaN. When a shell is semiconducting, a shell may in some variations comprise semiconducting nanoparticles. For example, a shell may comprise nanoparticles comprising ZnO, TiO₂, SnO₂, In₂O₃, Al₂O₃, or a combination thereof.

Thus, some methods for generating current may comprise using a mat wherein at least some of the nanostructures comprise GaN, and at least a portion of the nanoparticles comprise gold. Other methods for generating current may comprise using a mat wherein at least a portion of the nanostructures comprise a silica core and a shell comprising ZnO nanoparticles, with gold nanoparticles disposed on the shell and/or on the silica core.

In the methods, any variation of the solar energy capture devices as described herein may be used. For example, the methods may be used with solar energy capture devices that comprise two electrodes with the mat in electrical contact with the two electrodes, so that a photocurrent can be generated between the two electrodes. In other variations of the methods, the solar energy capture device may be configured as a Grätzel-type solar cell, wherein an electrolyte is disposed between two electrodes, and charge is transferred between the nanostructures and the electrolyte to generate a current between the two electrodes.

Methods for making photovoltaic devices are disclosed herein. These methods may for example result in structures as illustrated in FIGS. 6A and 6B as described above. The methods comprise electrically connecting a bottom side of a mat to a semiconducting substrate (e.g., silicon or doped silicon), where the semiconducting substrate is in electrical contact with the first electrode, and electrically connecting a top side of the mat to a second electrode such that current flows between the first and second electrodes when the mat and/or the semiconducting substrate is illuminated with solar radiation. A mat used in these methods comprises a plurality of nanostructures (e.g., substantially disordered nanostructures) with metal or metal alloy nanoparticles disposed thereon, as described herein. The methods may utilize a mat that is sandwiched between the first and second electrodes. In certain variations, the first and second electrodes may each be disposed on a back side of the device.

The methods may comprise growing the mat of nanostructures directly onto a substrate comprising a semiconducting (e.g., silicon or doped silicon such as amorphous silicon or polycrystalline silicon). For example, a substrate comprising the layers 607, 605, 604 and 603 may be used as a substrate on which to grow nanostructures. The nanostructures may be grown by any suitable technique, but in some cases they may be grown as described herein or in International Patent Publication WO 2007/002369, which has already been incorporated herein by reference in its entirety. Metal or metal alloy nanoparticles may then be deposited on the nanostructures at a desired density and having a desired distribution in terms of size, shape, and/or aspect ratio. Any suitable method may be used to deposit the nanoparticles on the nanostructures, e.g., the methods as described herein or described in International Patent Publication WO 2007/002369. Of course, as described herein, multiple layers of nanostructures may be grown to build up a mat having a desired thickness.

Some variations of the methods may comprise controlling a size and/or shape distribution of the nanoparticles to tune the absorption of the photovoltaic device. For example, the methods may comprise controlling a size and/or shape distribution of the nanoparticles so as to red-shift the absorption of the photovoltaic device relative to that of the silicon substrate, e.g., to visible wavelengths, near infrared wavelengths or infrared wavelengths.

### EXAMPLES

The properties of metal nanoparticles have been well studied and documented. For example, they can absorb light by the excitation of surface plasmons (oscillations of the electron gas). The resonance frequency of this oscillation depends on the size of the metal particles, their shape, and the type of metal. When the frequency of the incoming light is close to the resonance frequency of the surface plasmon, strong absorption can occur. Surface plasmon resonance (SPR) occurs normally in the visible part of the electromagnetic spectrum. For example, the typical resonance frequency for spherical Ag nanoparticles is at about 400 nm. However, nanoparticles with specific shapes and structures can exhibit SPRs at longer wavelengths into the IR spectrum.

Surface plasmons have been investigated for various applications, including surface-enhanced Raman scattering in which a roughened metal layer on a dielectric is used to enhance the Raman scattering signal from an absorbed sample species. The strongly enhanced signal allows for single-molecule detection. Surface plasmons are also used in the form of dielectric nanoparticles capped with a metallic layer. The spectral response of such a capped nanoparticle depends on the size of the nanoparticles and the thickness of the shell. By varying the size and thickness, the plasmon resonance can be tuned to different wavelengths. It has been shown that surface plasmons can eject electrons, generating a photocurrent. There has been an increasing interest in the utilization of these observations for solar energy capture.

The functionality is at the nanoscale (photon absorption is due to the size of the nanoparticles) but the devices can be scaled up to macroscopic dimensions because they do not depend on the performance of individual nanoparticles or nanostructures, but rather on the macroscopic collective structure. The growth conditions for the formation of nanostructures and their subsequent decoration with metal nanoparticles can be performed at temperatures low enough for the use of polymer substrates. This process opens up new manufacturing possibilities for integrating nanomaterials with polymer processing (e.g., forming microfluid devices, etc.) and enables the construction of various solar cell geometries (e.g., similar to those used for dye-sensitized nanocrystalline solar cells).

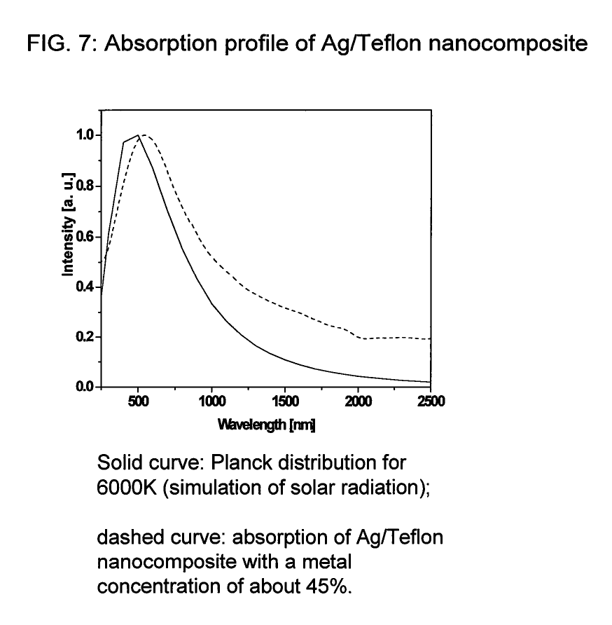

The microstructure of an Ag nanoparticle/Teflon AF nanocomposite can be tailored to exhibit a plasmon absorption band that closely matches the full solar spectrum as shown in FIG. 7. The polymer-metal nanocomposites were fabricated by vacuum evaporation in a chamber that allows for sequential as well as parallel evaporation of up to four different materials. For the synthesis of the Ag/Teflon AF nanocomposites, one pocket was filled with Teflon AF (grade 2400, granulates, DuPont®) and a second pocket was filled with silver (Alfa Aesar®, 99.999%, 1 mm diameter wires). Sapphire substrates were attached to a heated substrate holder, which was set to 120° C. Shutters were used to prevent premature deposition and a quartz crystal was used to monitor the evaporation rates. The relative evaporation rates were adjusted to fabricate nanocomposites with a range of metal concentrations.

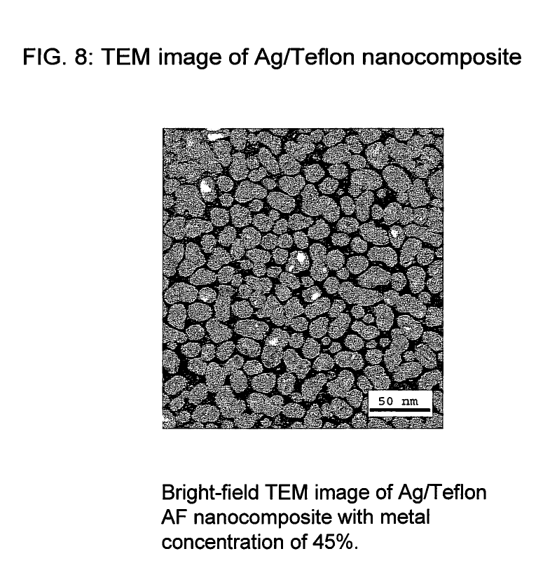

In general, for a broad absorption spectrum, the metal nanoparticles must have a range of sizes, as shown in the transmission electron microscope (TEM) image in FIG. 8. Further, in some cases it is desired that the metal nanoparticles be present in a composite at a concentration of ˜45 vol %. A broad distribution of particle shapes and sizes results in a broad distribution of resonance frequencies. These results demonstrate the potential of using isolated noble metal nanoparticles in photovoltaic (PV) applications. A limitation of using metal nanoparticles dispersed within a polymeric host matrix is the requirement for electronically conducting polymers, which are inherently intractable and not amenable to the vapor deposition processes used to make the polymer-based nanocomposites or to solution techniques used in low-cost polymer fabrication. The hole-transporting polymers π-conjugated) that would be vital to device operation are not possible to deposit by evaporation.

The method described herein uses the demonstrated absorption characteristics of noble metal nanoparticles and forms them onto semiconducting nanowires, which will serve as the conduits for the transport of charges.

McIlroy et al., described various methods for the fabrication of a variety of nanowire structures (e.g., ceramic nanowire structures) using vapor phase processes. See, e.g., D. N. McIlroy, et al., Phys. Rev. B 60, 4874 (1999), which is hereby incorporated by reference in its entirety. Recently, it has been shown that nanowires can be formed at low temperatures (down to about 300° C.), which allows them to be deposited onto low temperature substrates such as aluminum substrates or polymer substrates. See, e.g., L. Wang et al., Nanotechnology 17, 5298 (2006), which is hereby incorporated by reference herein in its entirety. This property alone opens up an enormous number of potential applications, in PV and many other areas, which would not be possible if nanowire formation was limited to high temperatures and rigid substrates.

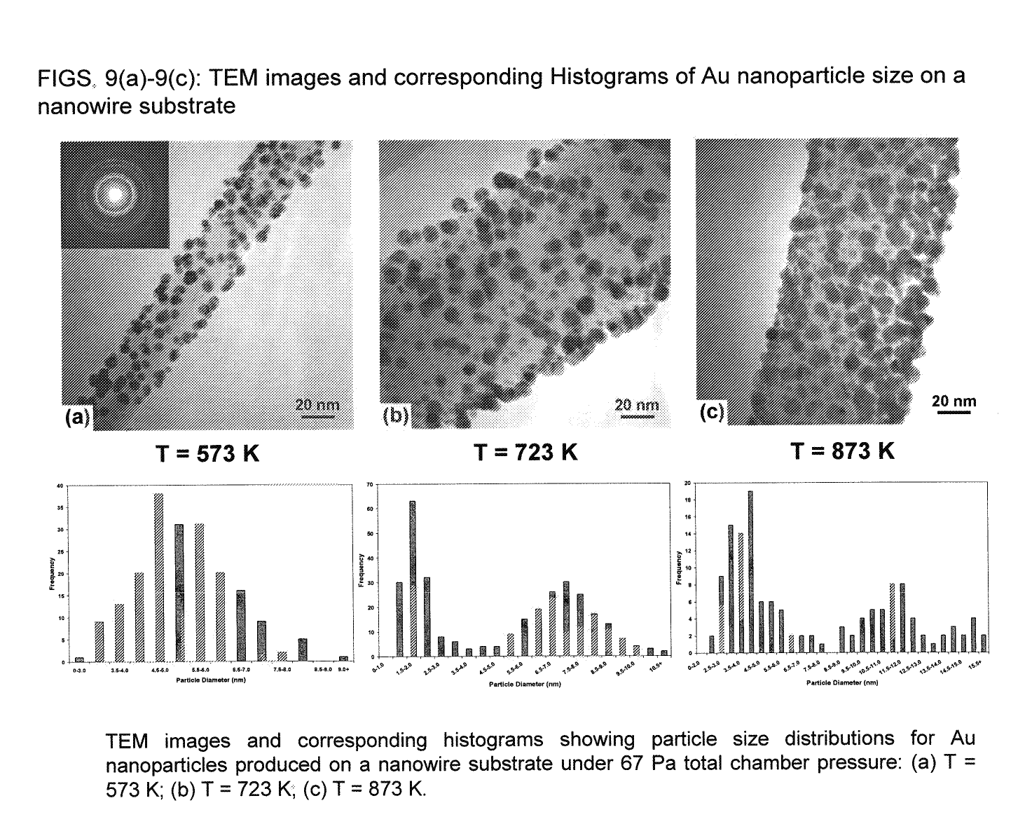

Metal nanoparticles can be deposited onto the nanowires as shown in FIGS. 9(a)-9(c). The nanoparticles are produced in a parallel plate plasma-enhanced chemical vapor deposition (PECVD) chamber operated at 13.56 MHz. The chamber volume is approximately 1 m³. The parallel plates are 3″ in diameter and 1.5″ apart. A nozzle protrudes from the center of the anode where the precursor/carrier gas mixture is introduced and the sample holder/heater serves as the ground plate. Argon is used as both the carrier and the background gas. The source compound is usually a powder and is selected based on the metal nanoparticles to be deposited and the ease of sublimation. For example, for the formation of Pt nanoparticles dimethyl(1,5-cyclooctadiene)platinum (II) [(CH₃)2Pt(C₈H₁₂)] is used as the source.

The sizes and size distribution of the nanoparticles can be controlled during deposition by variations in deposition temperature and chamber pressure, as shown in FIGS. 9(a)-9(c), for a specific chamber pressure of 67 Pa and different substrate temperatures.

Thus, by understanding the effect of deposition parameters on nanoparticle size, a broad size distribution can be selected that would allow a range of wavelengths to be absorbed.

A model, based on Maxwell-Garnett and Mie scattering theories, has been developed that allows for the determination of desired microstructural features of the system (e.g., nanoparticle size and shape and metal/dielectric combinations) for full solar spectrum absorption. Thus, a model based on Maxwell-Garnett and Mie scattering theories may be applied in the design of precious metal coated semiconductor nanowire samples.

In one embodiment, the nanowire material used is gallium nitride (GaN), but any coated nanowire substrate could be used, e.g., ZnO coated silica. GaN is a semiconducting material that can readily be formed as high aspect ratio nanowires and can easily be metallized. The GaN nanowires are grown in a tubular flow furnace. The nitrogen source is ammonia and the gallium source is a pellet of pure Ga.

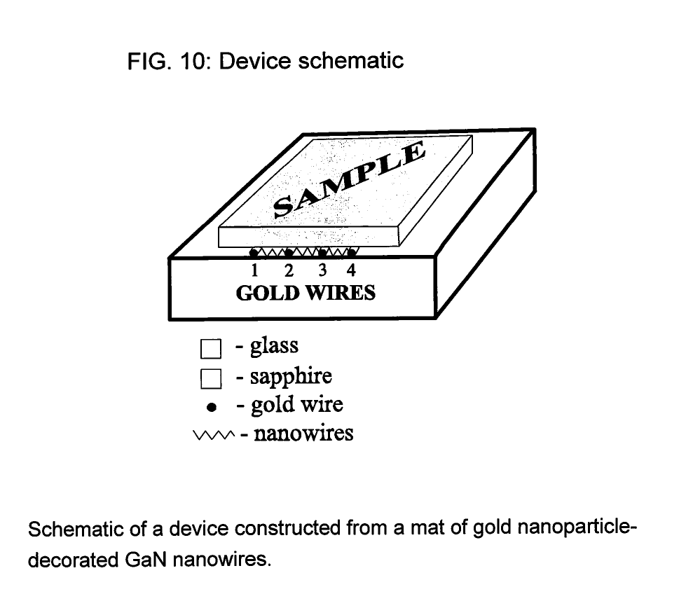

Devices were constructed using GaN nanowires decorated with Au nanoparticles using the geometry depicted in FIG. 10. The sample identified in FIG. 10 refers to the substrate upon which the semiconductor nanowire mat was grown. A similar geometry would be a reasonable starting point for determining PV properties because it comprises a mat of semiconductor nanowires decorated with metal nanoparticles sandwiched between two electrodes. An advantage of this design is the three-dimensional accessibility of the nanoparticles, as opposed to a planar surface covered by nanoparticles. In addition, the open structure of a nanowire mat is amenable to filling with a variety of materials for optimization of the PV properties of the device.

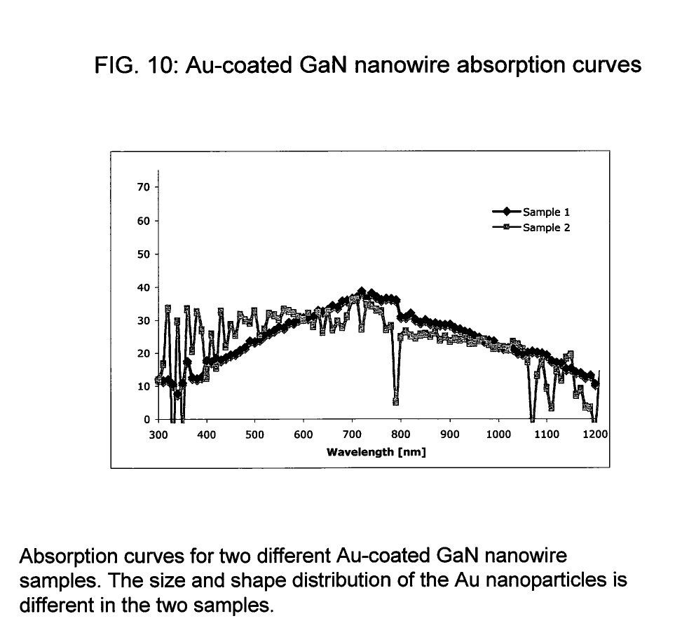

FIG. 11 shows some preliminary absorption measurements from an Au nanoparticle/GaN nanowire system demonstrating the potential for broad solar spectrum absorption. There, differing absorption spectra have been achieved for differing nanoparticle deposition conditions. These differing deposition conditions result in nanoparticles having differing sizes and/or shapes. These variations can be achieved by differing deposition conditions or by subsequent processing of the nanoparticle-decorated nanowires. Examples of subsequent processing steps include annealing and rapid thermal annealing.

The preceding description sets forth numerous exemplary configurations, parameters, and the like, that may be better understood with reference to U.S. and international applications, all of which are hereby incorporated by reference, in the entirety: U.S. Prov. App. 60/693,683, filed Jun. 24, 2005, U.S. Prov. App. 60/744,733, filed Apr. 12, 2006, and International App. PCT US06/024435, filed Jun. 23, 2006, published as WO/2007/002369 on Jan. 4, 2007.

What is claimed is:

1. A solar energy capture device comprising:
a first conductive or semiconducting electrode substrate; and
a first mat disposed on and in electrical contact with the first electrode substrate, the first mat comprising a plurality of semiconducting nanostructures oriented in a substantially disordered manner, and a plurality of metal or metal alloy nanoparticles having a distribution of sizes and/or shapes disposed on the nanostructures,
wherein the device is configured so that the first mat receives and absorbs solar radiation to result in charge carrier generation in the semiconducting nanostructures.

2. The solar energy capture device of claim 1, wherein an absorption spectrum of the first mat is tuned by adjusting a width of the distribution of sizes and/or shapes of the plurality of nanoparticles.

3. The solar energy capture device of claim 2, wherein an absorption spectrum of the first mat is tuned by adjusting an average size of the plurality of nanoparticles.

4. The solar energy capture device of claim 2, wherein an absorption spectrum of the first mat is tuned by adjusting an average aspect ratio of the plurality of nanoparticles.

5. The solar energy capture device of claim 2, wherein the distribution of size and/or shape of the nanoparticles is adjusted to increase absorption over a wavelength range from about 650 nm to about 2000 nm.

6. The solar energy capture device of claim 2, wherein the distribution of size and/or shape of the plurality of nanoparticles is multimodal.

7. The solar energy capture device of claim 6, wherein the distribution of size and/or shape of the plurality of nanoparticles is bimodal.

8. The solar energy capture device of claim 1, wherein the nanoparticles comprise a metal or metal alloy comprising gold, silver, copper, platinum, palladium, nickel, or a combination thereof.

9. The solar energy capture device of claim 1, wherein at least some of the nanostructures comprise ZnO, SnO₂, In₂O₃, Al₂O₃, TiO₂, SiC, GaN, or a combination thereof.

10. The solar energy capture device of claim 1, wherein at least some of the nanostructures comprise a core disposed at least partially within a shell.

11. The solar energy capture device of claim 10, wherein metal or metal alloy nanoparticles are disposed on the core and at least partially covered by the shell.

12. The solar energy capture device of claim 10, wherein metal or metal alloy nanoparticles are disposed on the shell.

13. The solar energy capture device of claim 10, wherein metal or metal alloy nanoparticles are disposed on the core and on the shell.

14. The solar energy capture device of claim 10, wherein the core is insulating and the shell is semiconducting.

15. The solar energy capture device of claim 10, wherein each of the core and shell are semiconducting, and one of the core and shell comprises a p-type semiconductor and the other of the core and shell comprises an n-type semiconductor.

16. The solar energy capture device of claim 10, wherein the core or shell comprises silica.

17. The solar energy capture device of claim 10, wherein the core or shell comprises GaN.

18. The solar energy capture device of claim 10, wherein the shell comprises semiconducting nanoparticles.

19. The solar energy capture device of claim 18, wherein the semiconducting nanoparticles comprise ZnO, TiO₂, SnO₂, In₂O₃, Al₂O₃, TiO₂ or a combination thereof.

20. The solar energy capture device of claim 19, wherein at least some of the nanostructures comprise a silica nanostructure core having ZnO nanoparticles disposed thereon.

21. The solar energy capture device of claim 1, wherein at least a portion of the nanostructures comprise GaN.

22. The solar energy capture device of claim 21, wherein at least a portion of the nanostructures comprise GaN, and at least a portion of the nanoparticles comprise gold.

23. The solar energy capture device of claim 20, wherein at least a portion of the nanostructures comprise a silica core, a shell comprising ZnO nanoparticles, and gold nanoparticles disposed on the shell and/or on the core.

24. The solar energy capture device of claim 1, wherein the first mat of nanostructures has a depth in a range from about 10 microns to about 500 microns extending outwardly from a surface of the first electrode substrate.

25. The solar energy capture device of claim 1, wherein a depth of the first mat extending outwardly from a surface of the first electrode substrate is selected to tune absorption of solar radiation by the first mat.

26. The solar energy capture device of claim 1, configured so that the first mat receives solar radiation at a non-normal angle of incidence relative to the first electrode substrate.

27. The solar energy capture device of 1, incorporated into a circuit so that photocurrent generated in the solar energy capture device drives a load in the circuit.

28. The solar energy capture device of claim 1, incorporated into a circuit so that photocurrent generated in the solar energy capture device is used to charge a charge storage device in the circuit.

29. The solar energy capture device of claim 1, further comprising an electrolyte in contact with the first mat, and wherein charge is transferred between the nanostructures on the first mat and the electrolyte.

30. The solar energy capture device of claim 1, further comprising a second conductive or semiconducting electrode substrate, wherein the first mat of semiconducting nanostructures is in electrical contact with the first and second electrode substrates.

31. The solar energy capture device of claim 1, further comprising a second conductive or semiconducting electrode substrate, and a second mat of semiconducting nanostructures disposed on the second electrode substrate.

32. The solar energy capture device of claim 31, wherein the first mat of semiconducting nanostructures on the first electrode substrate is in contact with an electrolyte, and the second mat of semiconducting nanostructures on the second electrode substrate is in contact with the electrolyte.

33. A solar energy capture system comprising multiple solar energy capture devices, the system including at least one of the solar energy capture devices of claim 1.

34. The solar energy capture system of claim 33, wherein each of the multiple solar energy capture devices preferentially absorbs different parts of the solar spectrum.

35. A method for generating current, the method comprising:
providing a solar energy capture device, the device comprising a mat of semiconducting nanostructures disposed on and in electrical contact with a first conductive or semiconducting electrode substrate, and a plurality of metal or metal alloy nanoparticles disposed on the nanostructures;
irradiating the device with solar radiation so that the metal or metal alloy nanoparticles disposed on the nanostructures absorb incident solar radiation and generate charge carriers in the nanostructures to generate a current.

36. The method of claim 35, wherein a distribution of size and/or shape of the plurality of nanoparticles has been selected to tune an absorption spectrum of the mat.

37. The method of claim 35, wherein the distribution of size and/or shape of the plurality of nanoparticles has been selected to increase absorption of the mat in a wavelength range from about 650 nm to about 2000 nm.

38. The method of claim 35, wherein the metal or metal alloy nanoparticles comprise gold, silver, copper, platinum, palladium, nickel, or a combination thereof.

39. The method of claim 35, comprising disposing the mat of nanostructure between first and second conductive or semiconducting electrode substrates, wherein the mat makes electrical contact with each of the first and second electrode substrates.

40. The method of claim 35, comprising contacting the nanostructures with an electrolyte, such that charge transfer occurs between the nanostructures and the electrolyte to result in current flow between the first and second electrode substrates.

41. A solar energy capture device, the device comprising:
a semiconductor photovoltaic solar panel comprising a first electrode, the solar panel configured to receive and absorb incident solar radiation; and
a mat electrically connected to the first electrode and to a second electrode, the mat configured to receive and absorb incident solar radiation,
wherein:
the mat comprises a plurality of semiconducting nanostructures and a plurality of metal or metal alloy nanoparticles disposed on the nanostructures; and
the device is configured so that the solar panel and the mat each absorb a portion of the incident solar radiation to generate current.

42. The solar energy capture device of claim 41, wherein the solar panel comprises a silicon layer disposed on the first electrode and an antireflective coating disposed on the silicon, and the mat of semiconducting nanostructures is electrically connected to the first electrode through the silicon layer and the antireflective coating.

43. The solar energy capture device of claim 41, wherein both the first and second electrodes are disposed on a rear side of the device.

44. The solar energy capture device of claim 41, wherein the second electrode comprises a patterned metal.

45. The solar energy capture device of claim 41, wherein the first and/or second electrodes comprise indium tin oxide.

46. The solar energy capture device of claim 41, wherein the solar radiation is incident upon the mat before being incident upon the silicon layer.

47. The solar energy capture device of claim 41, wherein the solar radiation is incident upon the silicon before being incident upon the mat.

48. The solar energy collector device of claim 41, wherein the mat is configured to extend the absorption of solar radiation by the device to the red relative to the photovoltaic solar panel.

49. The solar energy collector device of claim 41, wherein the photovoltaic solar panel comprises crystalline silicon.

50. The solar energy collector device of claim 41, wherein the photovoltaic solar panel comprises polycrystalline silicon.

51. The solar energy collector device of claim 41, wherein the photovoltaic solar panel comprises amorphous silicon.

52. The solar energy collector device of claim 41, where the photovoltaic solar panel comprises a thin film amorphous silicon layer.

53. The solar energy collector device of claim 41, configured to exhibit enhanced absorption at a wavelength in a range from about 500 nm to about 2000 nm compared to the photovoltaic solar panel.

54. The solar energy collector device of claim 41, wherein a distribution of a size and/or shape of the plurality of nanoparticles has been selected to tune an absorption of the mat.

55. The solar energy collector device of claim 41, wherein a depth of the mat has been selected to tune an absorption of the device.

56. A method for making a photovoltaic device, the method comprising:
electrically contacting a bottom side of a mat to a semiconducting substrate, the semiconducting substrate in electrical contact with a first electrode; and
electrically contacting a top side of the mat with a second electrode such that current flows between the first and second electrodes when the mat and/or the semiconducting substrate is illuminated with solar radiation,
wherein the mat comprises a plurality of nanostructures with metal or metal alloy nanoparticles disposed thereon.

57. The method of claim 56, wherein the mat is sandwiched between the first and the second electrodes.

58. The method of claim 56, wherein each of the first and second electrodes are disposed on a back side of the device.

59. The method of claim 58, comprising providing through holes in the silicon to form an electrical connection between the top side of the mat and the second electrode.

60. The method of claim 56, comprising controlling a distribution of size and/or shape of the metal or metal alloy nanoparticles and/or a thickness of the mat to tune the absorption of photovoltaic device.
